(19) United States
(12) Patent Application Publication
(10) Pub. No.: US 2026/0314224 A1
(43) Pub. Date: Oct. 8, 2026

(54) COLOR CONVERSION SUBSTRATE AND DISPLAY APPARATUS

(71) Applicants: Chengdu BOE Optoelectronics Technology Co., Ltd., Chengdu, Sichuan (CN); BOE Technology Group Co., Ltd., Beijing (CN)

(72) Inventors: Cheng Zeng, Beijing (CN); Jaeho Lee, Beijing (CN); Dongyu Gao, Beijing (CN); Lulin Ma, Beijing (CN); Qiyun Wang, Beijing (CN); Zhenye Wei, Beijing (CN)

(73) Assignees: Chengdu BOE Optoelectronics Technology Co., Ltd., Chengdu, Sichuan (CN); BOE Technology Group Co., Ltd., Beijing (CN)

(21) Appl. No.: 18/880,662

(22) PCT Filed: Jan. 3, 2023
(86) PCT No.: PCT/CN2023/070046

§ 371 Date: Jan. 2, 2025

(51) Int. Cl. H10K 59/38

(52) U.S. Cl. CPC H10K 59/38

(57) ABSTRACT

A color conversion substrate is provided. The color conversion substrate includes a base substrate; a pattern layer on the base substrate; a bank layer on a side of the pattern layer away from the base substrate; a color conversion layer at least partially in a plurality of first apertures extending through the bank layer, respectively; and a light transmissive layer at least partially in a plurality of second apertures extending through the bank layer, respectively. The pattern layer includes a plurality of pattern blocks. A respective pattern block of the plurality of pattern blocks protrudes away from the base substrate toward the bank layer.

### TECHNICAL FIELD

The present invention relates to display technology, more particularly, to a color conversion substrate and a display apparatus.

### BACKGROUND

Quantum dots material has excellent optical and electrical properties, including a narrow emission peak (with a half-peak width of approximately 30 nm), a tunable spectrum (ranging from visible light to infrared light), high photochemical stability, and a low starting voltage. Wavelengths of light emitted from quantum dots materials are tunable at least in part based on the particle sizes of the quantum dots. Due to these excellent properties, quantum dots have become a focus of research and development in the fields of display technology.

### SUMMARY

In one aspect, the present disclosure provides a color conversion substrate, comprising a base substrate; a pattern layer on the base substrate; a bank layer on a side of the pattern layer away from the base substrate; a color conversion layer at least partially in a plurality of first apertures extending through the bank layer, respectively; and a light transmissive layer at least partially in a plurality of second apertures extending through the bank layer, respectively; wherein the pattern layer comprises a plurality of pattern blocks; and a respective pattern block of the plurality of pattern blocks protrudes away from the base substrate toward the bank layer.

Optionally, a surface of the bank layer on a side closer to the pattern layer has a shape conforming to a surface of the pattern layer on a side closer to the bank layer.

Optionally, the pattern layer and the bank layer are at least partially in a light non-transmissive region; the pattern layer and the bank layer are at least partially absent in a plurality of light transmissive regions; and an orthographic projection of the bank layer on the base substrate at least partially overlaps with an orthographic projection of the respective pattern block on the base substrate.

Optionally, an orthographic projection of a surface of the bank layer on a side closer to the pattern layer on the base substrate covers an orthographic projection of the plurality of pattern blocks on the base substrate; and an area of the orthographic projection of the surface of the bank layer on a side closer to the pattern layer on the base substrate is at least 1.2 times of an area of the orthographic projection of the plurality of pattern blocks on the base substrate.

Optionally, the respective pattern block is in direct contact with the bank layer.

Optionally, the color conversion substrate further comprises an intermediate layer on a side of the pattern layer away from the base substrate, and on a side of the bank layer closer to the base substrate; wherein the respective pattern block is in direct contact with the intermediate layer; and the intermediate layer is in direct contact with the bank layer.

Optionally, the intermediate layer is at least partially present in a light non-transmissive region, and is at least partially absent in a plurality of light transmissive regions; and an orthographic projection of the intermediate layer on the base substrate is at least partially non-overlapping with an orthographic projection of the color conversion layer on the base substrate, and is at least partially non-overlapping with an orthographic projection of the light transmissive layer on the base substrate.

Optionally, the plurality of pattern blocks comprise a first adjacent pattern block and a second adjacent patter block in a portion of a light non-transmissive region between a first adjacent light transmissive region and a second adjacent light transmissive region of a plurality of light transmissive regions.

Optionally, a portion of the bank layer at least partially extends into a gap between the first adjacent pattern block and the second adjacent pattern block, and is in direct contact with the first adjacent pattern block and the second adjacent pattern block.

Optionally, the color conversion substrate further comprises an intermediate layer on a side of the first adjacent pattern block and the second adjacent pattern block away from the base substrate, the intermediate layer at least partially extending into a gap between the first adjacent pattern block and the second adjacent pattern block, and being in direct contact with the first adjacent pattern block and the second adjacent pattern block; and a groove extending into a portion of the intermediate layer at least partially extending into the gap; wherein a portion of the bank layer at least partially extends into the groove, and is in direct contact with the intermediate layer.

Optionally, the respective pattern block has a first side in contact with the base substrate, a second side opposite to the first side, a third side connecting the first side and the second side, and a fourth side connecting the first side and the second side, the third side and the fourth side opposite to each other.

Optionally, the bank layer at least partially covers the second side, the third side, and the fourth side of the respective pattern block.

Optionally, the color conversion substrate further comprises an intermediate layer on a side of the respective pattern block away from the base substrate; wherein the intermediate layer at least partially covers the second side, the third side, and the fourth side of the respective pattern block; and the bank layer at least partially covers a side of a portion of the intermediate layer that covers the second side of the respective pattern block, at least partially covers a side of a portion of the intermediate layer that covers the third side of the respective pattern block, and at least partially covers a side of a portion of the intermediate layer that covers the fourth side of the respective pattern block.

Optionally, the intermediate layer has a first refractive index; the pattern layer has a second refractive index; the base substrate has a third refractive index; the third refractive index is greater than the first refractive index; and the first refractive index is greater than the second refractive index.

Optionally, the first refractive index is in a range of 1.6 to 1.8; the second refractive index is in a range of 1.4 to 1.6; and the third refractive index is in a range of 1.80 to 1.90.

Optionally, the respective pattern block comprises a reflective material.

Optionally, the respective pattern block comprises a metallic material.

Optionally, the respective pattern block has an average thickness; the bank layer has a third average thickness; and a ratio of the third average thickness to the average thickness is in a range of 2 to 10.

Optionally, the first adjacent pattern block has a first average thickness; the second adjacent patter block has a second average thickness; the bank layer has a third average thickness; a ratio of the third average thickness to the first average thickness is in a range of 2 to 10; and a ratio of the third average thickness to the second average thickness is in a range of 2 to 10.

Optionally, the first adjacent pattern block and the second adjacent patter block are spaced apart be a minimum distance; in a cross-section along a plane perpendicular to the base substrate and intersecting the first adjacent pattern block and the second adjacent patter block, the first adjacent pattern block has a first width, and the second adjacent patter block has a second width; and a sum of the minimum distance, the first width, and the second width is less than a maximum width of a portion of a pixel definition layer in a display panel having the color conversion substrate, the portion of the pixel definition layer being between a first adjacent light transmissive region and a second adjacent light transmissive region of the plurality of light transmissive regions.

In another aspect, the present disclosure provides a display apparatus, comprising the color conversion substrate described herein, and a plurality of light emitting elements between a first base substrate and the pattern layer.

Optionally, the display apparatus further comprises an encapsulating layer encapsulating the plurality of light emitting elements; wherein the encapsulating layer comprises a first inorganic encapsulating sublayer, an organic encapsulating sublayer on a side of the first inorganic encapsulating sublayer away from the plurality of light emitting elements, and a second inorganic encapsulating sublayer on a side of the organic encapsulating sublayer away from the plurality of light emitting elements; and the pattern layer is in direct contact with the second encapsulating sublayer.

Optionally, the display apparatus further comprises a pixel definition layer defining a plurality of subpixel apertures; wherein an orthographic projection of the pixel definition layer on the base substrate covers an orthographic projection of the pattern layer on the base substrate.

### BRIEF DESCRIPTION OF THE FIGURES

The following drawings are merely examples for illustrative purposes according to various disclosed embodiments and are not intended to limit the scope of the present invention.

FIG. 1 is a schematic diagram illustrating the structure of a display panel in some embodiments according to the present disclosure.

FIG. 2 is a cross-sectional view along an A-A′ line in FIG. 1.

FIG. 3 is a plan view of a display panel in some embodiments according to the present disclosure.

FIG. 4 is a cross-sectional view of a display panel in some embodiments according to the present disclosure.

FIG. 5 is a cross-sectional view of a display panel in some embodiments according to the present disclosure.

FIG. 6A is a schematic diagram illustrating the structure of a light emitting element in some embodiments according to the present disclosure.

FIG. 6B is a schematic diagram illustrating the structure of a light emitting element in some embodiments according to the present disclosure.

FIG. 6C is a schematic diagram illustrating the structure of a light emitting element in some embodiments according to the present disclosure.

FIG. 7A is a schematic diagram illustrating the structure of a first color conversion block in some embodiments according to the present disclosure.

FIG. 7B is a schematic diagram illustrating the structure of a second color conversion block in some embodiments according to the present disclosure.

FIG. 7C is a schematic diagram illustrating the structure of a light transmissive block in some embodiments according to the present disclosure.

FIG. 8 illustrates a correlation between a thickness of the color conversion layer and a quantum dots conversion rate in some embodiments according to the present disclosure.

FIG. 9 is a cross-sectional view of a color conversion substrate in some embodiments according to the present disclosure.

FIG. 10 is a cross-sectional view of a display panel in some embodiments according to the present disclosure.

FIG. 11 is a cross-sectional view of a color conversion substrate in some embodiments according to the present disclosure.

FIG. 12 is a cross-sectional view of a display panel in some embodiments according to the present disclosure.

FIG. 13A is a plan view of a color conversion substrate in some embodiments according to the present disclosure.

FIG. 13B is a plan view of a color conversion substrate in some embodiments according to the present disclosure.

FIG. 14 illustrates a light non-transmissive region in some embodiments according to the present disclosure.

FIG. 15 is a plan view of a color conversion substrate in some embodiments according to the present disclosure.

FIG. 16 is a plan view of a color conversion substrate in some embodiments according to the present disclosure.

FIG. 17 is a plan view of a color conversion substrate in some embodiments according to the present disclosure.

FIG. 18 is a plan view of a color conversion substrate in some embodiments according to the present disclosure.

FIG. 19 is a plan view of a color conversion substrate in some embodiments according to the present disclosure.

FIG. 20 is a cross-sectional view of a pattern layer in some embodiments according to the present disclosure.

FIG. 21 is a cross-sectional view of a pattern layer in some embodiments according to the present disclosure.

FIG. 22 is a cross-sectional view of a pattern layer in some embodiments according to the present disclosure.

FIG. 23 is a cross-sectional view of two adjacent pattern blocks in some embodiments according to the present disclosure.

FIG. 24 is a cross-sectional view of a portion of an intermediate layer on two adjacent pattern blocks in some embodiments according to the present disclosure.

FIG. 25 is a cross-sectional view of a portion of a bank layer and a portion of an intermediate layer on two adjacent pattern blocks in some embodiments according to the present disclosure.

FIG. 26 is a cross-sectional view of a portion of a bank layer and a portion of an intermediate layer on two adjacent pattern blocks in some embodiments according to the present disclosure.

FIG. 27 illustrates a light path in a color conversion substrate in some embodiments according to the present disclosure.

FIG. 28 is a cross-sectional view of a color conversion substrate in some embodiments according to the present disclosure.

FIG. 29 is a cross-sectional view of a display panel in some embodiments according to the present disclosure.

FIG. 30 is a cross-sectional view of a color conversion substrate in some embodiments according to the present disclosure.

FIG. 31 is a plan view of a color conversion substrate in some embodiments according to the present disclosure.

FIG. 32 is a plan view of a color conversion substrate in some embodiments according to the present disclosure.

FIG. 33 is a plan view of a color conversion substrate in some embodiments according to the present disclosure.

FIG. 34 is a plan view of a color conversion substrate in some embodiments according to the present disclosure.

FIG. 35 is a cross-sectional view of a pattern layer in some embodiments according to the present disclosure.

FIG. 36 is a cross-sectional view of a pattern layer in some embodiments according to the present disclosure.

FIG. 37 is a cross-sectional view of a pattern layer in some embodiments according to the present disclosure.

FIG. 38 is a cross-sectional view of two adjacent pattern blocks in some embodiments according to the present disclosure.

FIG. 39 is a cross-sectional view of a color conversion substrate in some embodiments according to the present disclosure.

FIG. 40 is a cross-sectional view of a color conversion substrate in some embodiments according to the present disclosure.

FIG. 41 is a cross-sectional view of a respective pattern block in some embodiments according to the present disclosure.

FIG. 42 is a cross-sectional view of a portion of a bank layer on a respective pattern block in some embodiments according to the present disclosure.

FIG. 43 is a cross-sectional view of a portion of an intermediate layer on a respective pattern block in some embodiments according to the present disclosure.

FIG. 44 is a cross-sectional view of a portion of a bank layer and a portion of an intermediate layer on a respective pattern block in some embodiments according to the present disclosure.

FIG. 45 illustrates a light path in a color conversion substrate in some embodiments according to the present disclosure.

FIG. 46 is a cross-sectional view of a respective pattern block in some embodiments according to the present disclosure.

### DETAILED DESCRIPTION

The disclosure will now be described more specifically with reference to the following embodiments. It is to be noted that the following descriptions of some embodiments are presented herein for purpose of illustration and description only. It is not intended to be exhaustive or to be limited to the precise form disclosed.

The present disclosure provides, inter alia, a color conversion substrate and a display apparatus that substantially obviate one or more of the problems due to limitations and disadvantages of the related art. In one aspect, the present disclosure provides a color conversion substrate. In some embodiments, the color conversion substrate includes a base substrate; a pattern layer on the base substrate; a bank layer on a side of the pattern layer away from the base substrate; a color conversion layer at least partially in a plurality of first apertures extending through the bank layer, respectively; and a light transmissive layer at least partially in a plurality of second apertures extending through the bank layer, respectively. Optionally, the pattern layer comprises a plurality of pattern blocks. Optionally, a respective pattern block of the plurality of pattern blocks protrudes away from the base substrate toward the bank layer.

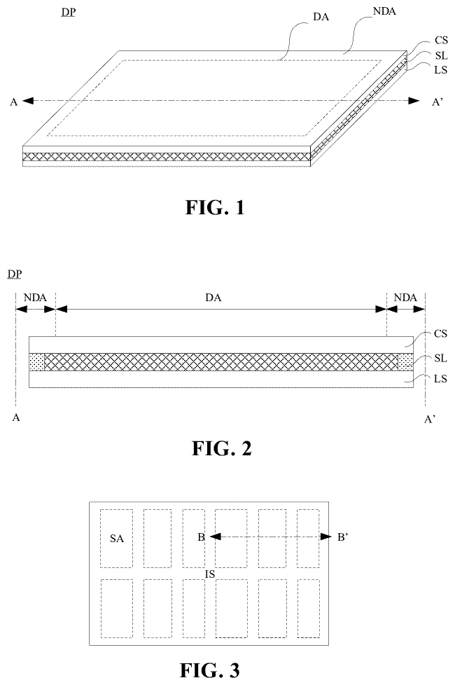

FIG. 1 is a schematic diagram illustrating the structure of a display panel in some embodiments according to the present disclosure. FIG. 2 is a cross-sectional view along an A-A′ line in FIG. 1. Referring to FIG. 1 and FIG. 2, the display panel DP in some embodiments includes a light emitting substrate LS, a color conversion substrate CS, and a spacer layer SL spacing apart the light emitting substrate LS and the color conversion substrate CS. The display panel DP includes a display area DA and a non-display area NDA.

FIG. 3 is a plan view of a display panel in some embodiments according to the present disclosure. Referring to FIG. 3, the display panel in some embodiments includes a plurality of subpixel regions SR and an inter-subpixel region ISR. As used herein, a subpixel region refers to a light emission region of a subpixel, such as a region corresponding to a pixel electrode in a liquid crystal display, or a region corresponding to a light emissive layer in a light emitting diode display panel, or a region corresponding to a color conversion block in a display panel according to the present disclosure. Optionally, a pixel may include a number of separate light emission regions corresponding to a number of subpixels in the pixel. Optionally, the subpixel region is a light emission region of a red color subpixel. Optionally, the subpixel region is a light emission region of a green color subpixel. Optionally, the subpixel region is a light emission region of a blue color subpixel. Optionally, the subpixel region is a light emission region of a white color subpixel. As used herein, an inter-subpixel region refers to a region between adjacent subpixel regions, such as a region corresponding to a black matrix in a liquid crystal display, or a region corresponding a pixel definition layer in a light emitting diode display panel, or a region corresponding to a bank layer in a display panel according to the present disclosure. Optionally, the inter-subpixel region is a region between adjacent subpixel regions in a same pixel. Optionally, the inter-subpixel region is a region between two adjacent subpixel regions from two adjacent pixels. Optionally, the inter-subpixel region is a region between a subpixel region of a red color subpixel and a subpixel region of an adjacent green color subpixel. Optionally, the inter-subpixel region is a region between a subpixel region of a red color subpixel and a subpixel region of an adjacent blue color subpixel. Optionally, the inter-subpixel region is a region between a subpixel region of a green color subpixel and a subpixel region of an adjacent blue color subpixel.

Various appropriate implementations may be practiced to make a display panel of the present disclosure. In one example, a light emitting substrate and a color conversion substrate are fabricated respectively, and then assembled together using a filler layer into a display panel. In another example, the color conversion substrate is directly fabricated on the light emitting substrate.

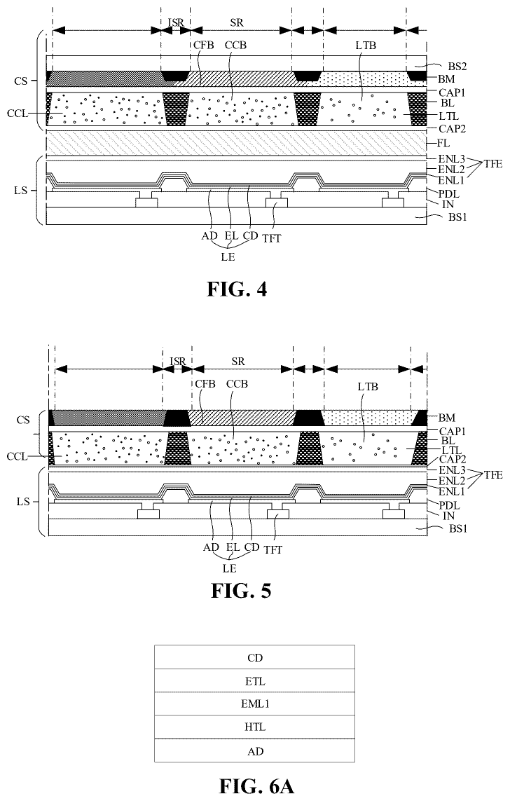

FIG. 4 is a cross-sectional view of a display panel in some embodiments according to the present disclosure. Referring to FIG. 4, the display panel in some embodiments includes a light emitting substrate LS and a color conversion substrate CS. The light emitting substrate LS and the color conversion substrate CS are assembled together. In some embodiments, the display panel further includes a filler layer FL between the light emitting substrate LS and the color conversion substrate CS, assembling the light emitting substrate LS and the color conversion substrate CS into the display panel.

FIG. 5 is a cross-sectional view of a display panel in some embodiments according to the present disclosure. Referring to FIG. 5, the display panel is absent of a filler layer. The color conversion substrate CS is directly on the light emitting substrate LS, for example, directly on a surface of a second inorganic encapsulating sublayer ENL3 of the light emitting substrate LS.

Referring to FIG. 4 and FIG. 5, in some embodiments, the light emitting substrate LS includes a first base substate BS1; a plurality of thin film transistor TFT (e.g., transistors in pixel driving circuits) on the first base substate BS1; an insulating layer IN on a side of the plurality of transistor TFT away from the first base substate BS1; a pixel definition layer PDL and a plurality of light emitting elements LE on a side of the insulating layer IN away from the first base substate BS1; and an encapsulating layer TFE on a side of the plurality of light emitting elements LE and the pixel definition layer PDL away from the first base substate BS1. A respective light emitting element of the plurality of light emitting elements LE includes an anode AD, a light emitting layer EL on a side of the anode AD away from the first base substate BS1, and a cathode CD on a side of the light emitting layer EL away from the first base substate BS1. In one example, the encapsulating layer TFE include a first inorganic encapsulating sublayer ENL1, an organic encapsulating sublayer ENL2 on a side of the first inorganic encapsulating sublayer ENL1 away from the first base substate BS1, and a second inorganic encapsulating sublayer ENL3 on a side of the organic encapsulating sublayer ENL2 away from the first base substate BS1.

Referring to FIG. 4 and FIG. 5, in some embodiments, the color conversion substrate CS includes a bank layer BL defining a plurality of apertures, a color conversion layer CCL and a light transmissive layer LTL at least partially in the plurality of apertures defined by the bank layer BL. The color conversion layer CCL includes a plurality of color conversion blocks CCB. The light transmissive layer LTL includes a plurality of light transmissive blocks LTB.

In some embodiments, the color conversion substrate further includes a first cap layer CAP1 on a side of the bank layer BL, the color conversion layer CCL, and the light transmissive layer LTL away from the base substrate BBS.

The color conversion substrate CS in some embodiments further includes a color filter CF on the color conversion layer CCL and the light transmissive layer LTL. The color filter CF includes a plurality of color filter blocks CFB. An orthographic projection of a respective color filter block of the plurality of color filter blocks CFB on a base substrate at least partially overlaps with an orthographic projection of a respective color conversion block or a respective light transmissive block on the base substrate. Orthographic projections of adjacent color filter blocks may partially overlap with each other, e.g., along the edges.

The color conversion substrate CS in some embodiments further includes a black matrix BM on a side of the color filter CF away from the color conversion layer CCL and the light transmissive layer LTL. The black matrix BM is in the inter-subpixel region ISR. A respective color filter block, a respective color conversion block, or a respective light transmissive block is at least partially in an individual subpixel region. Optionally, the color conversion substrate CS includes a second cap layer CAP2 on a side of the color filter CF closer to the bank layer BL, the color conversion layer CCL, and the light transmissive layer LTL. The color conversion substrate CS optionally includes a second cap layer CAP2 on a side of the bank layer BL, the color conversion layer CCL, and the light transmissive layer LTL away from the color filter CF.

In some embodiments, the light transmissive layer LTL is a light scattering layer, and the plurality of light transmissive blocks LTB are a plurality of light scattering blocks.

In some embodiments, the display panel is a quantum dots display panel. In a quantum dots display panel, a light source (e.g., a blue light source) is used to excite quantum dots to emit light based on the photoluminescence excitation principle. In some embodiments, the plurality of color conversion blocks CCB include a first color conversion block and a second color conversion block. In one example, the first color conversion block is configured to convert a light of a third color (e.g., a blue light) into a light of a first color (e.g., a red light). In another example, the second color conversion block is configured to convert the light of the third color (e.g., a blue light) into a light of a second color (e.g., a green light). The plurality of light transmissive blocks LTB do not convert a color of the incident light. Optionally, the plurality of light transmissive blocks LTB are configured to scatter the incident light (e.g., a blue light), which emits through a color filter block for image display. The plurality of color filter blocks CFB includes a color filter block of a first color (e.g., a red color filter block) corresponding to the first color conversion block, a color filter block of a second color (e.g., a green color filter block) corresponding to the second color conversion block, and a color filter block of a third color (e.g., a blue color filter block) corresponding to a light transmissive block.

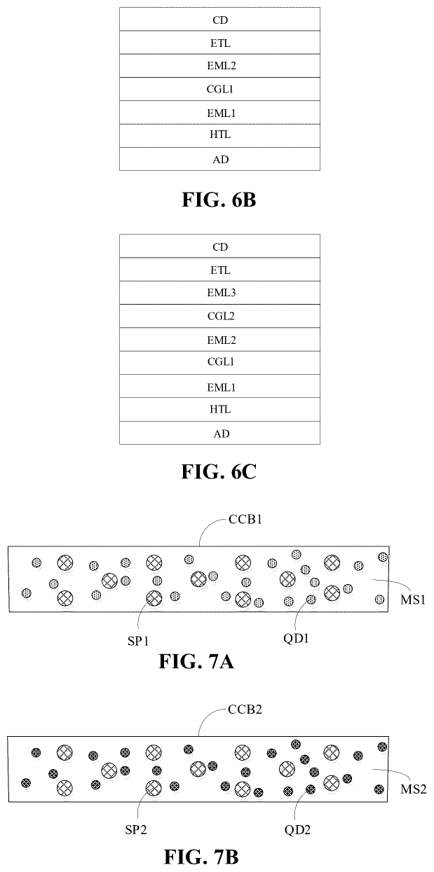

Various appropriate light emitting elements may be implemented in the display panel according to the present disclosure. FIG. 6A is a schematic diagram illustrating the structure of a light emitting element in some embodiments according to the present disclosure. Referring to FIG. 6A, the light emitting element in some embodiments includes an anode AD, a hole transport layer HTL on the anode AD, a first light emitting layer EML1 on a side of the hole transport layer HTL away from the anode AD, an electron transport layer ETL on a side of the first light emitting layer EML1 away from the hole transport layer HTL, and a cathode CD on a side of the electron transport layer ETL away from the first light emitting layer EML1.

In some embodiments, the light emitting element may have a stacked structure. FIG. 6B is a schematic diagram illustrating the structure of a light emitting element in some embodiments according to the present disclosure. Referring to FIG. 6B, the light emitting element in some embodiments includes an anode AD, a hole transport layer HTL on the anode AD, a first light emitting layer EML1 on a side of the hole transport layer HTL away from the anode AD, a first charge generation layer CGL1 on a side of the first light emitting layer EML1 away from the hole transport layer HTL, a second light emitting layer EML2 on a side of the first charge generation layer CGL1 away from the first light emitting layer EML1, an electron transport layer ETL on a side of the second light emitting layer EML2 away from the first charge generation layer CGL1, and a cathode CD on a side of the electron transport layer ETL away from the second light emitting layer EML2.

FIG. 6C is a schematic diagram illustrating the structure of a light emitting element in some embodiments according to the present disclosure. Referring to FIG. 6C, the light emitting element in some embodiments includes an anode AD, a hole transport layer HTL on the anode AD, a first light emitting layer EML1 on a side of the hole transport layer HTL away from the anode AD, a first charge generation layer CGL1 on a side of the first light emitting layer EML1 away from the hole transport layer HTL, a second light emitting layer EML2 on a side of the first charge generation layer CGL1 away from the first light emitting layer EML1, a second charge generation layer CGL2 on a side of the second light emitting layer EML2 away from the first charge generation layer CGL1, a third light emitting layer EML3 on a side of the second charge generation layer CGL2 away from the second light emitting layer EML2, an electron transport layer ETL on a side of the third light emitting layer EML3 away from the second charge generation layer CGL2, and a cathode CD on a side of the electron transport layer ETL away from the second light emitting layer EML3.

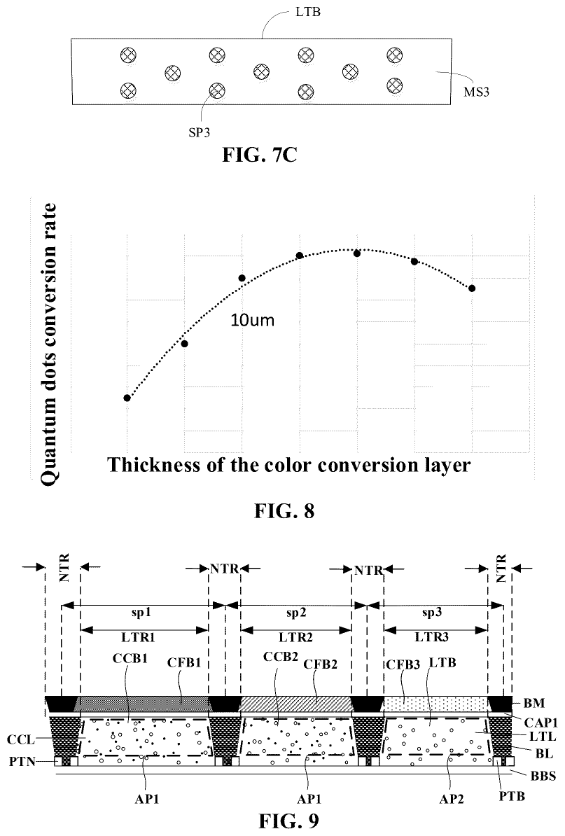

FIG. 7A is a schematic diagram illustrating the structure of a first color conversion block in some embodiments according to the present disclosure. Referring to FIG. 7A, the first color conversion block CCB1 is a color conversion block configured to convert a light of a third color (e.g., a blue light) into a light of a first color (e.g., a red light). In some embodiments, the first color conversion block CCB1 includes a first matrix MS1, a plurality of first scattering particles SP1 and a plurality of first quantum dots QD1 dispersed in the first matrix MS1. The first matrix MS1 may include a polymer material such as an organic polymer material. Examples of appropriate polymer materials for making the first matrix MS1 include epoxy resins, acrylic resins, polyurethane resins, silicone resins, and silane resins. Examples of appropriate materials for making the plurality of first scattering particles SP1 include TiO₂, ZnO, ZrO₂, Al₂O₃, SiO₂. Examples of appropriate quantum dots materials for making the plurality of first quantum dots QD1 include a quantum dots material of a first color (e.g., a red color). The quantum dots material may include a material selected from a group consisting of CdS, CdSe, ZnSe, InP, PbS, CsPbCl3, CsPbBr3, CsPhI3, CdS/ZnS, CdSe/ZnS, InP/ZnS, PbS/ZnS, CsPbCl3/ZnS, CsPbBr3/ZnS, and CsPhI3/ZnS.

FIG. 7B is a schematic diagram illustrating the structure of a second color conversion block in some embodiments according to the present disclosure. Referring to FIG. 7B, the second color conversion block CCB2 is a color conversion block configured to convert a light of a third color (e.g., a blue light) into a light of a second color (e.g., a green light). In some embodiments, the second color conversion block CCB2 includes a second matrix MS2, a plurality of second scattering particles SP2 and a plurality of second quantum dots QD2 dispersed in the second matrix MS2. The second matrix MS2 may include a polymer material such as an organic polymer material. Examples of appropriate polymer materials for making the second matrix MS2 include epoxy resins, acrylic resins, polyurethane resins, silicone resins, and silane resins. Examples of appropriate materials for making the plurality of second scattering particles SP2 include TiO₂, ZnO, ZrO₂, Al₂O₃, SiO₂. Examples of appropriate quantum dots materials for making the plurality of second quantum dots QD2 include a quantum dots material of a second color (e.g., a green color). The quantum dots material may include a material selected from a group consisting of CdS, CdSe, ZnSe, InP, PbS, CsPbCl3, CsPbBr3, CsPhI3, CdS/ZnS, CdSe/ZnS, InP/ZnS, PbS/ZnS, CsPbCl3/ZnS, CsPbBr3/ZnS, and CsPhI3/ZnS.

FIG. 7C is a schematic diagram illustrating the structure of a light transmissive block in some embodiments according to the present disclosure. Referring to FIG. 7C, the light transmissive block LTB in some embodiments includes a third matrix MS3 and a plurality of third scattering particles SP3 dispersed in the third matrix MS3. The third matrix MS3 may include a polymer material such as an organic polymer material. Examples of appropriate polymer materials for making the third matrix MS3 include epoxy resins, acrylic resins, polyurethane resins, silicone resins, and silane resins. Examples of appropriate materials for making the plurality of third scattering particles SP3 include TiO₂, ZnO, ZrO₂, Al₂O₃, SiO₂.

In one example, the first matrix MS1, the second matrix MS2, and the third matrix MS3 includes a same polymer material. In another example, at least two of the first matrix MS1, the second matrix MS2, and the third matrix MS3 includes different polymer materials.

In one example, the first scattering particles SP1, the second scattering particles SP2, and the third scattering particles SP3 includes a same scattering material. In another example, at least two of the first scattering particles SP1, the second scattering particles SP2, and the third scattering particles SP3 includes different scattering materials.

FIG. 8 illustrates a correlation between a thickness of the color conversion layer and a quantum dots conversion rate in some embodiments according to the present disclosure. The inventors of the present disclosure discover that the quantum dots conversion rate is correlated to the thickness of the color conversion layer. In general, the quantum dots conversion rate increases with the thickness of the color conversion layer. Due to the limitations by the material used in fabricating the color conversion layer, the maximum thickness of the color conversion layer in related color conversion substrate is typically only approximately 10 μm, less than the optimal thickness value for achieving the maximum quantum dots conversion rate.

The inventors of the present disclosure discover that, in related color conversion substrates, the bank layer is prone to peeling off due to insufficient adhesion between the bank layer and its underlying layer (typically an encapsulating layer). The inventors of the present disclosure discover that, surprisingly and unexpectedly, the intricate structure of the color conversion substrate significantly improves performance of the color conversion substrate. A contact area between the bank layer and its underlying structure is greatly increased by the unique structure of the color conversion substrate according to the present disclosure. The color conversion substrate also allows deposition of a color conversion layer with a greater thickness and an enhanced light emission efficiency. Moreover, the color conversion substrate has a higher quantum dots conversion rate.

FIG. 9 is a cross-sectional view of a color conversion substrate in some embodiments according to the present disclosure. Referring to FIG. 9, the color conversion substrate in some embodiments includes a pattern layer PTN on a base substrate BBS; a bank layer BL on a side of the pattern layer PTN away from the base substrate BBS; a plurality of first apertures AP1 and a plurality of second apertures AP2 extending through the bank layer BL; a color conversion layer CCL at least partially in the plurality of first apertures AP1; and a light transmissive layer LTL at least partially in the plurality of second apertures AP2.

In some embodiments, the color conversion substrate further includes a first cap layer CAP1 on a side of the bank layer BL, the color conversion layer CCL, and the light transmissive layer LTL away from the base substrate BBS.

In some embodiments, the color conversion substrate further includes a color filter CF on a side of the color conversion layer CCL and the light transmissive layer LTL away from the base substrate BBS. In some embodiments, the color filter CF includes a plurality of color filter blocks (e.g., a color filter block of a first color CFB1, a color filter block of a second color CFB2, and a color filter block of a third color CFB3). An orthographic projection of a respective color filter block of the plurality of color filter blocks CFB on a base substrate at least partially overlaps with an orthographic projection of a respective color conversion block or a respective light scattering block on the base substrate. Orthographic projections of adjacent color filter blocks may partially overlap with each other, e.g., along the edges.

In some embodiments, the color conversion substrate further includes a black matrix BM on a side of the color filter CF away from the color conversion layer CCL and the light scattering layer LSL.

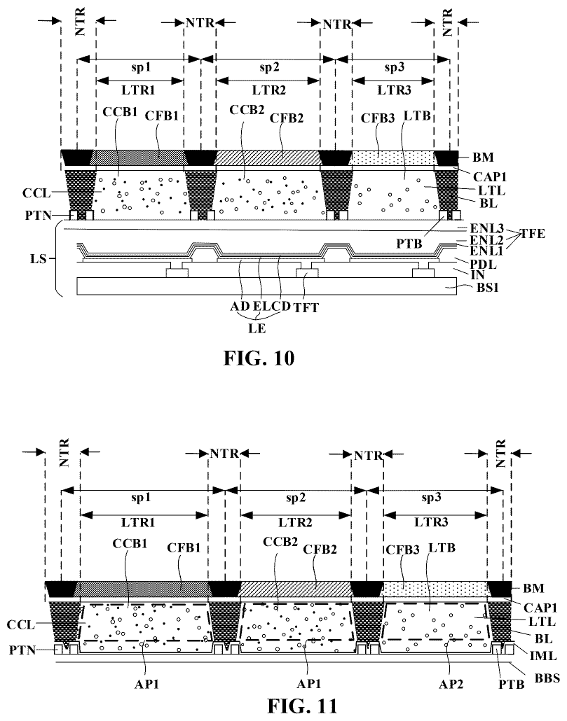

Depending on application scenarios, various appropriate layers may be implemented as the base substrate BBS. In one example, referring to FIG. 4 or FIG. 5, the base substrate BBS in some embodiments may be a second cap layer CAP2. In another example, the base substrate BBS in some embodiments may be a second inorganic encapsulating sublayer ENL3. FIG. 10 is a cross-sectional view of a display panel in some embodiments according to the present disclosure. Referring to FIG. 10, the pattern layer PTN is on the second encapsulating sublayer ENL3 (equivalent to the base substrate BBS in FIG. 9). In one example, the pattern layer PTN is in direct contact with the second encapsulating sublayer ENL3.

FIG. 11 is a cross-sectional view of a color conversion substrate in some embodiments according to the present disclosure. Referring to FIG. 11, the color conversion substrate in some embodiments includes a pattern layer PTN on a base substrate BBS; an intermediate layer IML on a side of the pattern layer PTN away from the base substrate BBS; a bank layer BL on a side of the intermediate layer IML away from the base substrate BBS; a plurality of first apertures AP1 and a plurality of second apertures AP2 extending through the bank layer BL; a color conversion layer CCL at least partially in the plurality of first apertures AP1; and a light transmissive layer LTL at least partially in the plurality of second apertures AP2.

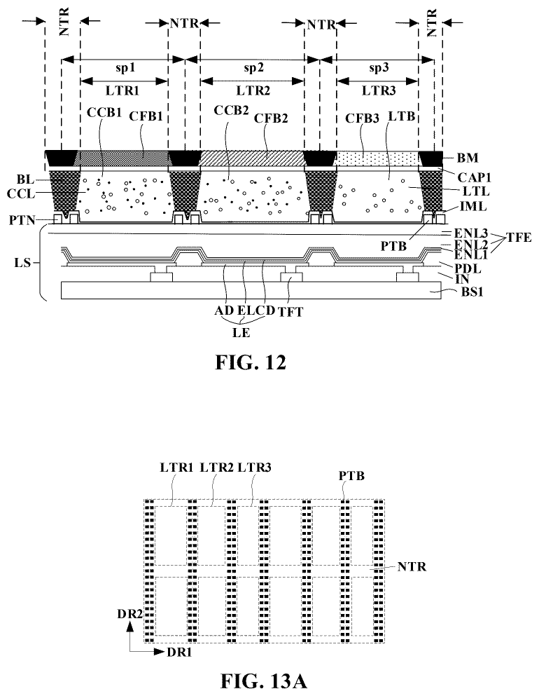

FIG. 12 is a cross-sectional view of a display panel in some embodiments according to the present disclosure. Referring to FIG. 12, the pattern layer PTN is on the second encapsulating sublayer ENL3 (equivalent to the base substrate BBS in FIG. 11). In one example, the pattern layer PTN is in direct contact with the second encapsulating sublayer ENL3.

In one particular example, the intermediate layer IML is an additional encapsulating layer, as depicted in FIG. 12.

In some embodiments, the color conversion substrate includes a plurality of subpixels. In some embodiments, the color conversion substrate includes a plurality of light transmissive regions and a light non-transmissive region. Optionally, the plurality of light transmissive regions are the same as the plurality of subpixel regions SR depicted in FIG. 4 or FIG. 5, and the light non-transmissive region is the same as the inter-subpixel region ISR depicted in FIG. 4 or FIG. 5.

Referring to FIG. 9 to FIG. 12, the plurality of subpixels includes a first subpixel sp1, a second subpixel sp2, and a third subpixel sp3. As shown in FIG. 9 to FIG. 12, the plurality of light transmissive regions include a first light transmissive region LTR1 in the first subpixel sp1, a second light transmissive region LTR2 in the second subpixel sp2, a third light transmissive region LTR3 in the third subpixel sp3, and a light non-transmissive region NTR. In some embodiments, the pattern layer PTN is at least partially in the light non-transmissive region NTR. Optionally, the pattern layer PTN is completely in the light non-transmissive region NTR. The intermediate layer IML is at least partially in the light non-transmissive region NTR. Optionally, the intermediate layer IML is at least partially in the light non-transmissive region NTR, and at least partially in a light transmissive region (e.g., the first light transmissive region LTR1, the second light transmissive region LTR2, and the third light transmissive region LTR3).

In some embodiments, the black matrix BM is at least partially in the light non-transmissive region NTR. Optionally, the black matrix BM is completely in the light non-transmissive region NTR.

In some embodiments, the bank layer BL is at least partially in the light non-transmissive region NTR. Optionally, the bank layer BL is completely in the light non-transmissive region NTR.

In some embodiments, a respective color filter block of the plurality of color filter blocks is at least partially in a respective light transmissive region of the plurality of light transmissive regions. Optionally, at least 80% (e.g., at least 85%, at least 90%, at least 95%, at least 99%, or 100%) of the respective color filter block is in the respective light transmissive region.

In some embodiments, a respective color conversion block of the plurality of color conversion blocks is at least partially in a first individual light transmissive region of the plurality of light transmissive regions. Optionally, at least 80% (e.g., at least 85%, at least 90%, at least 95%, at least 99%, or 100%) of the respective color conversion block is in the first individual light transmissive region.

In some embodiments, a respective light transmissive block of the plurality of light transmissive blocks is at least partially in a second individual light transmissive region of the plurality of light transmissive regions. Optionally, at least 80% (e.g., at least 85%, at least 90%, at least 95%, at least 99%, or 100%) of the respective light transmissive block is in the second individual light transmissive region.

Referring to FIG. 9 to FIG. 12, in some embodiments, an orthographic projection of the pixel definition layer PDL on the base substrate BBS at least partially overlaps with an orthographic projection of the pattern layer PTN on the base substrate BBS. Optionally, the orthographic projection of the pixel definition layer PDL on the base substrate BBS covers the orthographic projection of the pattern layer PTN on the base substrate BBS.

In some embodiments, an orthographic projection of the bank layer BL on the base substrate BBS at least partially overlaps with an orthographic projection of the pattern layer PTN on the base substrate BBS. Optionally, the orthographic projection of the bank layer BL on the base substrate BBS covers the orthographic projection of the pattern layer PTN on the base substrate BBS.

In some embodiments, an orthographic projection of the black matrix BM on the base substrate BBS at least partially overlaps with an orthographic projection of the pattern layer PTN on the base substrate BBS. Optionally, the orthographic projection of the black matrix BM on the base substrate BBS covers the orthographic projection of the pattern layer PTN on the base substrate BBS.

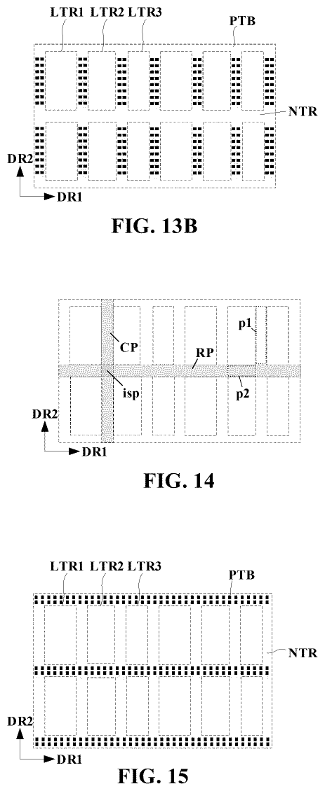

FIG. 13A is a plan view of a color conversion substrate in some embodiments according to the present disclosure. Referring to FIG. 9 to FIG. 13A, the pattern layer PTN in some embodiments includes a plurality of pattern blocks PTB. A respective pattern block of the plurality of pattern blocks PTB protrudes away from the base substrate BBS, e.g., toward the bank layer BL. Referring to FIG. 9 and FIG. 10, the respective pattern block in some embodiments is in direct contact with the bank layer BL. Referring to FIG. 11 and FIG. 12, the respective pattern block in some embodiments is in direct contact with the intermediate layer IML, and the intermediate layer IML is in direct contact with the bank layer BL.

FIG. 14 illustrates a light non-transmissive region in some embodiments according to the present disclosure. Referring to FIG. 14, the light non-transmissive region NTR in some embodiments includes a plurality of row portions RP and a plurality of column portions CP. The plurality of row portions RP and the plurality of column portions CP intersect each other, forming a plurality of intersection portions isp. The light non-transmissive region NTR includes a plurality of first portions p1. A respective first portion of the plurality of first portions p1 of the light non-transmissive region NTR is a portion between two adjacent light transmissive regions of the plurality of light transmissive regions arranged along a first direction DR1. The light non-transmissive region NTR includes a plurality of second portions p2, a respective second portion of the plurality of second portions p2 of the light non-transmissive region NTR is a portion between two adjacent light transmissive regions of the plurality of light transmissive regions arranged along a second direction DR2.

The plurality of pattern blocks PTB may be arranged in various appropriate manners. Referring to FIG. 13A and FIG. 14, the plurality of pattern blocks PTB in some embodiments are at least partially in the plurality of column portions CP. In some embodiments, the plurality of pattern blocks PTB are at least partially absent in the plurality of row portions RP. Optionally, the plurality of pattern blocks PTB are absent in the plurality of row portions RP except for the plurality of intersection portions isp.

In some embodiments, the plurality of pattern blocks PTB are at least partially in the plurality of first portions p1 of the light non-transmissive region NTR. Optionally, the plurality of pattern blocks PTB are at least partially in the plurality of first portions p1 of the light non-transmissive region NTR, and at least partially in the plurality of intersection portions isp of the light non-transmissive region NTR. Optionally, the plurality of pattern blocks PTB are at least partially absent in the plurality of second portions p2. Optionally, the plurality of pattern blocks PTB are completely absent in the plurality of second portions p2.

In some embodiments, the plurality of pattern blocks PTB include a plurality of first arrays, a respective first array of the plurality of first arrays being in a respective column portion of the plurality of column portions CP. In some embodiments, pattern blocks in the respective first array is arranged in rows and columns. Optionally, a column of pattern blocks are arranged along a second direction DR2, and a row of pattern blocks are arranged along the first direction DR1. Optionally, the respective first array includes two columns of pattern blocks.

In some embodiments, pattern blocks in the respective first array in the respective column portion have a mirror symmetry with respect to a plane perpendicular to the base substrate and parallel to the second direction DR2. In some embodiments, columns of pattern blocks in the respective first array in the respective column portion have a translational symmetry along the first direction DR1.

FIG. 13B is a plan view of a color conversion substrate in some embodiments according to the present disclosure. Referring to FIG. 13B and FIG. 14, the plurality of pattern blocks PTB in some embodiments are at least partially in the plurality of first portions p1. Optionally, the plurality of pattern blocks PTB are at least partially absent in the plurality of second portions p2. Optionally, the plurality of pattern blocks PTB are at least partially absent in the plurality of intersection portions isp. As shown in FIG. 13B, the plurality of pattern blocks PTB are absent in the plurality of second portions p2 and absent in the plurality of intersection portions isp.

FIG. 15 is a plan view of a color conversion substrate in some embodiments according to the present disclosure. Referring to FIG. 15 and FIG. 14, the plurality of pattern blocks PTB in some embodiments are at least partially in the plurality of row portions RP. In some embodiments, the plurality of pattern blocks PTB are at least partially absent in the plurality of column portions CP. Optionally, the plurality of pattern blocks PTB are absent in the plurality of column portions CP except for the plurality of intersection portions isp.

In some embodiments, the plurality of pattern blocks PTB are at least partially in the plurality of second portions p2 of the light non-transmissive region NTR. Optionally, the plurality of pattern blocks PTB are at least partially in the plurality of second portions p2 of the light non-transmissive region NTR, and at least partially in the plurality of intersection portions isp of the light non-transmissive region NTR. Optionally, the plurality of pattern blocks PTB are at least partially absent in the plurality of first portions p1. Optionally, the plurality of pattern blocks PTB are completely absent in the plurality of first portions p1.

In some embodiments, the plurality of pattern blocks PTB include a plurality of second arrays, a respective second array of the plurality of second arrays being in a respective row portion of the plurality of row portions RP. In some embodiments, pattern blocks in the respective second array is arranged in rows and columns. Optionally, a column of pattern blocks are arranged along a second direction DR2, and a row of pattern blocks are arranged along the first direction DR1. Optionally, the respective second array includes two rows of pattern blocks.

In some embodiments, pattern blocks in the respective second array in the respective row portion have a mirror symmetry with respect to a plane perpendicular to the base substrate and parallel to the first direction DR1. In some embodiments, rows of pattern blocks in the respective second array in the respective row portion have a translational symmetry along the second direction DR2.

FIG. 16 is a plan view of a color conversion substrate in some embodiments according to the present disclosure. Referring to FIG. 16 and FIG. 14, the plurality of pattern blocks PTB in some embodiments are at least partially in the plurality of column portions CP. In some embodiments, the plurality of pattern blocks PTB are at least partially absent in the plurality of row portions RP. Optionally, the plurality of pattern blocks PTB are absent in the plurality of row portions RP except for the plurality of intersection portions isp.

In some embodiments, the plurality of pattern blocks PTB are at least partially in the plurality of first portions p1 of the light non-transmissive region NTR. Optionally, the plurality of pattern blocks PTB are at least partially in the plurality of first portions p1 of the light non-transmissive region NTR, and at least partially in the plurality of intersection portions isp of the light non-transmissive region NTR. Optionally, the plurality of pattern blocks PTB are at least partially absent in the plurality of second portions p2. Optionally, the plurality of pattern blocks PTB are completely absent in the plurality of second portions p2.

In some embodiments, the plurality of pattern blocks PTB include a plurality of first arrays, a respective first array of the plurality of first arrays being in a respective column portion of the plurality of column portions CP. In some embodiments, pattern blocks in the respective first array is arranged in columns. Optionally, a column of pattern blocks is arranged along a second direction DR2. Optionally, the respective first array includes two columns of pattern blocks. In some embodiments, pattern blocks in two adjacent columns in the respective first array are staggered with respect to each other. Optionally, the respective first array in the respective column portion lacks a mirror symmetry with respect to a plane perpendicular to the base substrate and parallel to the second direction DR2.

FIG. 17 is a plan view of a color conversion substrate in some embodiments according to the present disclosure. Referring to FIG. 17 and FIG. 14, the plurality of pattern blocks PTB in some embodiments are at least partially in the plurality of row portions RP. In some embodiments, the plurality of pattern blocks PTB are at least partially absent in the plurality of column portions CP. Optionally, the plurality of pattern blocks PTB are absent in the plurality of column portions CP except for the plurality of intersection portions isp.

In some embodiments, the plurality of pattern blocks PTB are at least partially in the plurality of second portions p2 of the light non-transmissive region NTR. Optionally, the plurality of pattern blocks PTB are at least partially in the plurality of second portions p2 of the light non-transmissive region NTR, and at least partially in the plurality of intersection portions isp of the light non-transmissive region NTR. Optionally, the plurality of pattern blocks PTB are at least partially absent in the plurality of first portions p1. Optionally, the plurality of pattern blocks PTB are completely absent in the plurality of first portions p1.

In some embodiments, the plurality of pattern blocks PTB include a plurality of second arrays, a respective second array of the plurality of second arrays being in a respective row portion of the plurality of row portions RP. In some embodiments, pattern blocks in the respective second array is arranged in rows. Optionally, a row of pattern blocks is arranged along the first direction DR1. Optionally, the respective second array includes two rows of pattern blocks. In some embodiments, pattern blocks in two adjacent rows in the respective second array are staggered with respect to each other. Optionally, the respective second array in the respective row portion lacks a mirror symmetry with respect to a plane perpendicular to the base substrate and parallel to the first direction DR1.

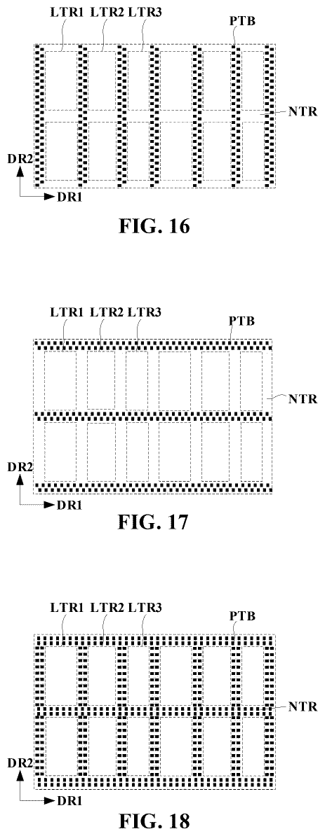

FIG. 18 is a plan view of a color conversion substrate in some embodiments according to the present disclosure. Referring to FIG. 18 and FIG. 14, the plurality of pattern blocks PTB in some embodiments are at least partially in the plurality of column portions CP, and at least partially in the plurality of row portions RP. In some embodiments, the plurality of pattern blocks PTB are at least partially in the plurality of first portions p1 of the light non-transmissive region NTR, and are at least partially in the plurality of second portions p2. Optionally, the plurality of pattern blocks PTB are at least partially in the plurality of intersection portions isp of the light non-transmissive region NTR.

In some embodiments, the plurality of pattern blocks PTB include a plurality of third arrays, a respective third array of the plurality of third arrays being in a respective first portion of the plurality of first portions p1. In some embodiments, pattern blocks in the respective third array is arranged in rows and columns. Optionally, a column of pattern blocks is arranged along a second direction DR2, and a row of pattern blocks is arranged along the first direction DR1. Optionally, the respective third array includes two columns of pattern blocks.

In some embodiments, pattern blocks in the respective third array in the respective column portion have a mirror symmetry with respect to a plane perpendicular to the base substrate and parallel to the second direction DR2. In some embodiments, columns of pattern blocks in the respective third array in the respective first portion have a translational symmetry along the first direction DR1.

In some embodiments, the plurality of pattern blocks PTB include a plurality of fourth arrays, a respective fourth array of the plurality of fourth arrays being in a respective second portion of the plurality of second portions p2. In some embodiments, pattern blocks in the respective fourth array is arranged in rows and columns. Optionally, a column of pattern blocks is arranged along a second direction DR2, and a row of pattern blocks is arranged along the first direction DR1. Optionally, the respective fourth array includes two rows of pattern blocks.

In some embodiments, pattern blocks in the respective fourth array in the respective second portion have a mirror symmetry with respect to a plane perpendicular to the base substrate and parallel to the first direction DR1. In some embodiments, rows of pattern blocks in the respective fourth array in the respective row portion have a translational symmetry along the second direction DR2.

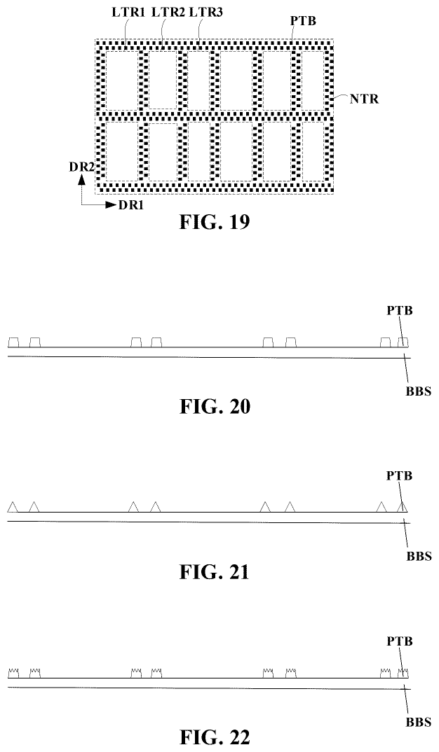

FIG. 19 is a plan view of a color conversion substrate in some embodiments according to the present disclosure. Referring to FIG. 19 and FIG. 14, the plurality of pattern blocks PTB in some embodiments are at least partially in the plurality of column portions CP, and at least partially in the plurality of row portions RP. In some embodiments, the plurality of pattern blocks PTB are at least partially in the plurality of first portions p1 of the light non-transmissive region NTR, and are at least partially in the plurality of second portions p2. Optionally, the plurality of pattern blocks PTB are at least partially in the plurality of intersection portions isp of the light non-transmissive region NTR.

In some embodiments, the plurality of pattern blocks PTB include a plurality of third arrays, a respective third array of the plurality of third arrays being in a respective first portion of the plurality of first portions p1. In some embodiments, pattern blocks in the respective third array is arranged in columns. Optionally, a column of pattern blocks is arranged along a second direction DR2. Optionally, the respective third array includes two columns of pattern blocks. In some embodiments, pattern blocks in two adjacent columns in the respective first array are staggered with respect to each other. Optionally, the respective third array in the respective column portion lacks a mirror symmetry with respect to a plane perpendicular to the base substrate and parallel to the second direction DR2.

In some embodiments, the plurality of pattern blocks PTB include a plurality of fourth arrays, a respective fourth array of the plurality of fourth arrays being in a respective second portion of the plurality of second portions p2. In some embodiments, pattern blocks in the respective fourth array is arranged in rows. Optionally, a row of pattern blocks is arranged along the first direction DR1. Optionally, the respective fourth array includes two rows of pattern blocks. In some embodiments, pattern blocks in two adjacent rows in the respective fourth array are staggered with respect to each other. Optionally, the respective fourth array in the respective row portion lacks a mirror symmetry with respect to a plane perpendicular to the base substrate and parallel to the first direction DR1.

The respective pattern block may have various appropriate morphology. In one example, referring to FIG. 9 to FIG. 12, in a cross-section along a plane perpendicular to the base substrate BBS and intersecting two adjacent pattern blocks of the plurality of pattern blocks PTB, the respective pattern block has a rectangular shape. FIG. 20 is a cross-sectional view of a pattern layer in some embodiments according to the present disclosure. In some embodiments, referring to FIG. 20, in a cross-section along a plane perpendicular to the base substrate BBS and intersecting two adjacent pattern blocks of the plurality of pattern blocks PTB, the respective pattern block has a trapezoidal shape.

FIG. 21 is a cross-sectional view of a pattern layer in some embodiments according to the present disclosure. In some embodiments, referring to FIG. 21, in a cross-section along a plane perpendicular to the base substrate BBS and intersecting two adjacent pattern blocks of the plurality of pattern blocks PTB, the respective pattern block has a triangular shape.

FIG. 22 is a cross-sectional view of a pattern layer in some embodiments according to the present disclosure. In some embodiments, referring to FIG. 22, a side of the respective pattern block away from the base substrate BBS has a serrated surface. By having the serrated surface, the bank layer BL has an increased contact area with an underlying layer, and the bank layer BL can be better adhered.

Examples of other appropriate shapes of the respective pattern block, in the cross-section along a plane perpendicular to the base substrate BBS and intersecting two adjacent pattern blocks of the plurality of pattern blocks PTB, include an inverted trapezoidal shape, a square shape, a partial circle shape, and so on.

The respective pattern block may have various appropriate three-dimensional shapes. Examples of appropriate three-dimensional shapes include cylinder, cone, cube, cuboid, hexagonal prism, triangular prism, tetrahedron, and pyramid.

In some embodiments, the plurality of pattern blocks PTB have a same morphology. For example, in a cross-section along a plane perpendicular to the base substrate BBS and intersecting two adjacent pattern blocks of the plurality of pattern blocks PTB, the plurality of pattern blocks PTB have a same shape. Optionally, pattern blocks in two adjacent columns have a same morphology. Optionally, pattern blocks in two adjacent rows have a same morphology.

In some embodiments, at least two pattern blocks of the plurality of pattern blocks PTB have different morphology. For example, in a cross-section along a plane perpendicular to the base substrate BBS and intersecting two adjacent pattern blocks of the plurality of pattern blocks PTB, at least two pattern blocks of the plurality of pattern blocks PTB have different shapes. Optionally, pattern blocks in two adjacent columns have different morphology. Optionally, pattern blocks in two adjacent rows have different morphology.

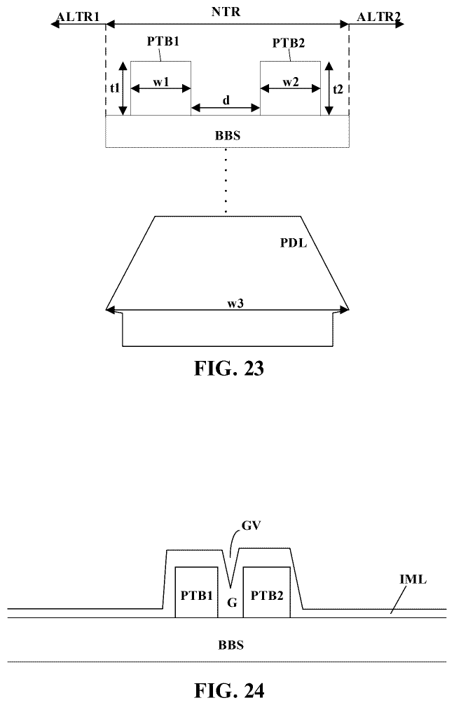

FIG. 23 is a cross-sectional view of two adjacent pattern blocks in some embodiments according to the present disclosure. Referring to FIG. 23, the two adjacent pattern blocks include a first adjacent pattern block PTB1 and a second adjacent patter block PTB2. In one example, the first adjacent pattern block PTB1 and the second adjacent patter block PTB2 are in a same column portion. In an alternative example, the first adjacent pattern block PTB1 and the second adjacent patter block PTB2 are in a same row portion. In an alternative example, the first adjacent pattern block PTB1 and the second adjacent patter block PTB2 are in a same intersection portion. In an alternative example, the first adjacent pattern block PTB1 and the second adjacent patter block PTB2 are in a same first portion. In an alternative example, the first adjacent pattern block PTB1 and the second adjacent patter block PTB2 are in a same second portion.

In some embodiments, the first adjacent pattern block PTB1 and the second adjacent patter block PTB2 are spaced apart be a minimum distance d. In some embodiments, the first adjacent pattern block PTB1 has a first average thickness t1. In some embodiments, the second adjacent patter block PTB2 has a second average thickness t2. In some embodiments, in a cross-section along a plane perpendicular to the base substrate BBS and intersecting the first adjacent pattern block PTB1 and the second adjacent patter block PTB2, the first adjacent pattern block PTB1 has a first width w1, and the second adjacent patter block PTB2 has a second width w2. In some embodiments, in a cross-section along a plane perpendicular to the base substrate BBS and intersecting the first adjacent pattern block PTB1 and the second adjacent patter block PTB2, a portion of the pixel definition layer PDL between a first adjacent light transmissive region ALTR1 and a second adjacent light transmissive region ALTR2 of the plurality of light transmissive regions has a maximum width w3.

In one example, w1 and w2 are substantially the same. In an alternative example, w1 and w2 are different from each other.

In one example, 1 μm≤w1≤10 μm, 1 μm≤w2≤10 μm, and 1 μm≤d≤10 μm.

In one example, t1 and t2 are substantially the same. In an alternative example, t1 and t2 are different from each other.

In one example, 1 μm≤t1≤5 μm, and 1 μm≤t2≤5 μm.

In some embodiments, a sum of w1, w2, and d is less than w3.

In some embodiments, the bank layer has an average thickness t3. In some embodiments, 2≤t3/t1≤10, e.g., 2≤t3/t1≤3, 3≤t3/t1≤4, 4≤t3/t1≤5,5≤t3/t1≤6,6≤t3/t1≤7, 7≤t3/t1≤8, 8≤t3/t1≤9, or 9≤t3/t1≤10. In some embodiments, 2≤t3/t2≤10, e.g., 2≤t3/t2≤3, 3≤t3/t2≤4, 4≤t3/t2≤5, 5≤t3/t2≤6, 6≤t3/t2≤7, 7≤t3/t2≤8, 8≤t3/t2 ≤9, or 9≤t3/t2≤10.

In some embodiments, referring to FIG. 9 to FIG. 12, and FIG. 23, in a cross-section along a plane perpendicular to the base substrate BBS and intersecting the plurality of pattern blocks PTB, pattern blocks closest to a respective light transmissive block of the plurality of light transmissive blocks LTB has a first average thickness t1, and pattern blocks closest to a respective color conversion block of the plurality of color conversion blocks (e.g., the first color conversion block CCB1 or the second color conversion block CCB2) has a second average thickness t2. Optionally, t1 and t2 are different from each other. In one example, t1>t2. In an alternative example, t2>t1.

Various appropriate materials and fabrication methods may be used for forming the plurality of pattern blocks PTB. Examples of appropriate material for making the plurality of pattern blocks PTB include an organic insulating material, a metallic material, an inorganic insulating material, a reflective material, or any combination thereof. Examples of organic insulating materials for making the plurality of pattern blocks PTB include methacrylate, cinnamate, polyurethane resin, silicone resin, and silane resin. Examples of metallic materials for making the plurality of pattern blocks PTB include aluminum, silver, gold, and copper. The plurality of pattern blocks PTB may be formed by lithography, imprinting, nano-imprinting, and sputtering.

In some embodiments, surfaces of the plurality of pattern blocks PTB may be treated to increase their roughness thereby increasing contact areas with a layer on top of the plurality of pattern blocks PTB. In particular, when the bank layer is formed to be in direct contact with the plurality of pattern blocks PTB, an increased roughness of the surfaces of the plurality of pattern blocks PTB can increase contact areas between the bank layer and the plurality of pattern blocks PTB, enhancing adhesion of the bank layer to the pattern layer PTN. For example, the surfaces of the plurality of pattern blocks PTB may be treated with plasma or ultraviolet ozone treatment.

In some embodiments, the plurality of pattern blocks PTB have a refractive index in a

The inventors of the present disclosure discover that, in related color conversion substrates, the bank layer is prone to peeling off due to insufficient adhesion between the bank layer and its underlying layer (typically an encapsulating layer). The inventors of the present disclosure discover that, surprisingly and unexpectedly, the intricate structure of the color conversion substrate significantly improves performance of the color conversion substrate. A contact area between the bank layer and its underlying structure (e.g., through the presence of the pattern layer) is greatly increased by the unique structure of the color conversion substrate according to the present disclosure. The color conversion substrate also allows deposition of a color conversion layer with a greater thickness and an enhanced light emission efficiency. Moreover, the color conversion substrate has a higher quantum dots conversion rate.

Referring to FIG. 11 and FIG. 12, the color conversion substrate in some embodiments further includes an intermediate layer IML on a side of the pattern layer PTN away from the base substrate BBS, and on a side of the pattern layer PTN closer to the bank layer BL. Optionally, the respective pattern block is in direct contact with the intermediate layer IML, and the intermediate layer IML is in direct contact with the bank layer BL.

Various appropriate materials may be used for making the intermediate layer IML. Examples of materials suitable for making the intermediate layer IML include, but are not limited to, silicon oxide (SiOy), silicon nitride (SiNy, e.g., Si₃N₄), silicon oxynitride (SiOₓN_{y}), aluminum oxide, barium oxide, and calcium oxide.

FIG. 24 is a cross-sectional view of a portion of an intermediate layer on two adjacent pattern blocks in some embodiments according to the present disclosure. Referring to FIG. 24, in some embodiments, a portion of the intermediate layer IML is at least partially in a gap G between the first adjacent pattern block PTB1 and the second adjacent pattern block PTB2. Optionally, the color conversion substrate includes a groove GV extending partially into a portion of the intermediate layer IML that is on top of or in the gap G. Optionally, the groove GV at least partially extends into the gap G between the first adjacent pattern block PTB1 and the second adjacent pattern block PTB2.

In some embodiments, a portion of the bank layer BL at least partially extends into the gap G between the first adjacent pattern block PTB1 and the second adjacent pattern block PTB2. Referring to FIG. 9, in some embodiments, a portion of the bank layer BL extends into the gap G, and is in direct contact with the first adjacent pattern block PTB1 and the second adjacent pattern block PTB2. Referring to FIG. 24, a portion of the bank layer BL extends into the groove GV, and the groove GV partially extends into the gap G between the first adjacent pattern block PTB1 and the second adjacent pattern block PTB2. The portion of the bank layer BL partially extends into the gap G, and is in direct contact with the intermediate layer IML.

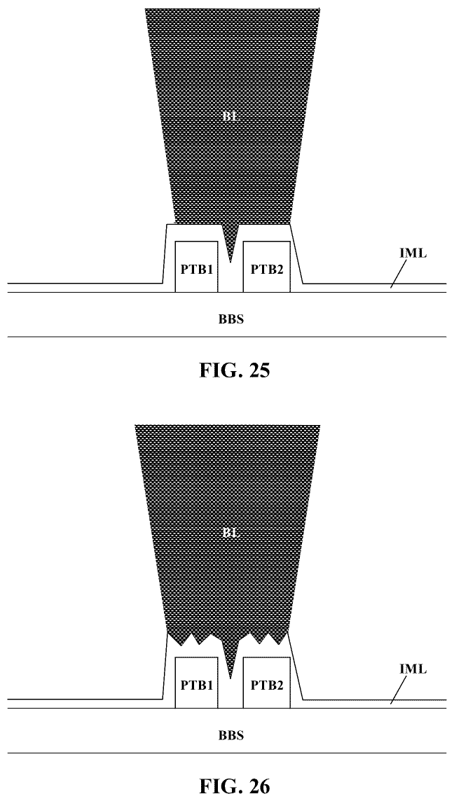

FIG. 25 is a cross-sectional view of a portion of a bank layer and a portion of an intermediate layer on two adjacent pattern blocks in some embodiments according to the present disclosure. Referring to FIG. 24 and FIG. 25, the bank layer BL in some embodiments at least partially extends into the groove GV. By having the plurality of pattern blocks, and by having the groove GV at least partially extends into the gap G between the first adjacent pattern block PTB1 and the second adjacent pattern block PTB2, a contact area between the bank layer BL and an underlying layer (e.g., the intermediate layer IML) can be increased, enhancing adhesion of the bank layer BL to the underlying layer.

FIG. 26 is a cross-sectional view of a portion of a bank layer and a portion of an intermediate layer on two adjacent pattern blocks in some embodiments according to the present disclosure. Referring to FIG. 26, a surface of the portion of the intermediate layer IML on a side of the first adjacent pattern block PTB1 and the second adjacent pattern block PTB2 away from the base substrate BBS in some embodiments may be treated (e.g., with plasma or ultraviolet ozone treatment) to form a serrated surface. By having the serrated surface, the bank layer BL has an increased contact area with an underlying layer (e.g., the intermediate layer IML), and the bank layer BL can be better adhered.

In some embodiments, the intermediate layer IML has a first refractive index, and the pattern layer PTN has a second refractive index. Optionally, the first refractive index is greater than the second refractive index. In one example, the first refractive index is in a range of 1.6 to 1.8, and the second refractive index is in a range of 1.4 to 1.6. In one example, the intermediate layer IML has a thickness in a range of 0.5 μm to 2.0 μm.

In some embodiments, the base substrate BBS has a third refractive index, the intermediate layer IML has a first refractive index, and the pattern layer PTN has a second refractive index. Optionally, the third refractive index is greater than the first refractive index, and the first refractive index is greater than the second refractive index. In one example, the third refractive index is in a range of 1.80 to 1.90 (e.g., 1.85), the first refractive index is in a range of 1.70 to 1.75, and the second refractive index is in a range of 1.5 to 1.6.

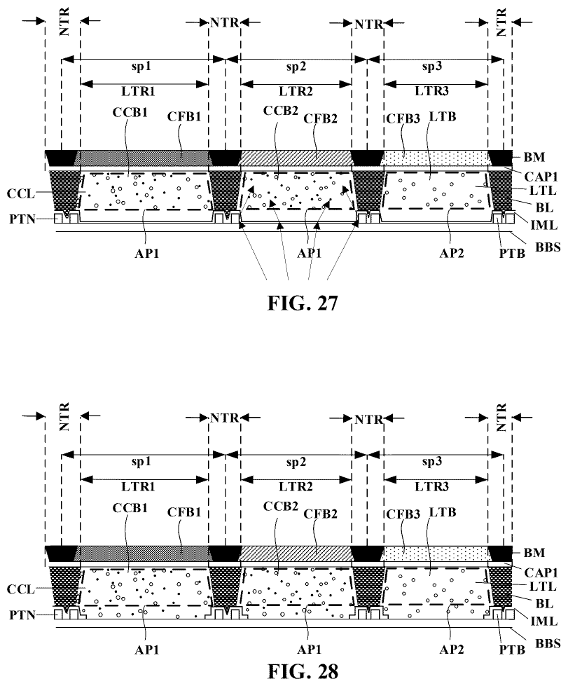

FIG. 27 illustrates a light path in a color conversion substrate in some embodiments according to the present disclosure. Referring to FIG. 27, by having the first refractive index greater than the second refractive index, or having the third refractive index greater than the first refractive index, incident light irradiated on a respective pattern block can be refracted toward a center of a respective light transmissive region (e.g., the first light transmissive region LTR1, the second light transmissive region LTR2, or the third light transmissive region LTR3). For example, the incident light to the respective light transmissive region can be converged, leading to excitation of quantum dots materials with a better incident angle, thereby enhancing an enhanced quantum dots conversion rate.

In some embodiments, the plurality of pattern blocks PTB include a reflective material such as a metallic material. Incident light irradiated on a respective pattern block can be reflected by a surface of the respective pattern block toward a center of a respective light transmissive region (e.g., the first light transmissive region LTR1, the second light transmissive region LTR2, or the third light transmissive region LTR3), particularly for incident light with a relatively greater incident angle. Moreover, by having the third refractive index greater than the first refractive index, incident light with a relatively smaller incident angle can be refracted toward the center of a respective light transmissive region. The combination of the above mechanisms results in convergence of the incident light entered into the respective light transmissive region, leading to excitation of quantum dots materials with a better incident angle, thereby enhancing an enhanced quantum dots conversion rate.

In one example, the respective pattern block is made of a metallic material.

In an alternative example, the respective pattern block includes a reflective material and an insulating material. Optionally, the reflective material is on a side of the insulating material away from the base substrate BBS. Optionally, the respective pattern block includes a base portion and a coating portion on a side of the base portion away from the base substrate BBS. The coating portion is made of a reflective material such as a metallic material, and the base portion is made of an insulating material such as an organic insulating material. Optionally, the coating portion at least partially covers lateral surfaces of the base portion.

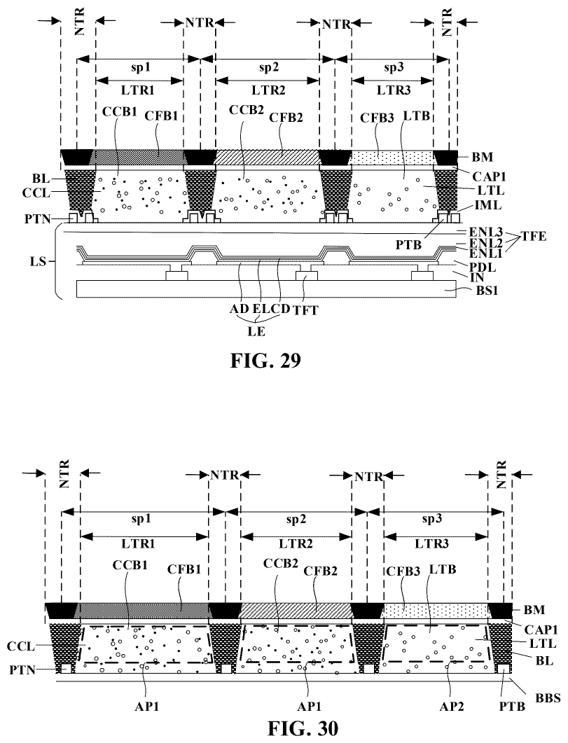

FIG. 28 is a cross-sectional view of a color conversion substrate in some embodiments according to the present disclosure. FIG. 29 is a cross-sectional view of a display panel in some embodiments according to the present disclosure. Referring to FIG. 28 and FIG. 29, the color conversion substrate in some embodiments includes a pattern layer PTN on a base substrate BBS; an intermediate layer IML on a side of the pattern layer PTN away from the base substrate BBS; a bank layer BL on a side of the intermediate layer IML away from the base substrate BBS; a plurality of first apertures AP1 and a plurality of second apertures AP2 extending through the bank layer BL; a color conversion layer CCL at least partially in the plurality of first apertures AP1; and a light transmissive layer LTL at least partially in the plurality of second apertures AP2.

Referring to FIG. 11 and FIG. 12, the intermediate layer IML in some embodiments extends over the plurality of light transmissive regions (e.g., the first light transmissive region LTR1, the second light transmissive region LTR2, or the third light transmissive region LTR3) and the light non-transmissive region NTR. In some embodiments, referring to FIG. 11 and FIG. 12, an orthographic projection of the intermediate layer IML on the base substrate BBS covers an orthographic projection of the color conversion layer CCL and the light transmissive layer LTL on the base substrate BBS.

Referring to FIG. 28 and FIG. 29, the intermediate layer IML in some embodiments is at least partially present in the light non-transmissive region NTR, and is at least partially absent in the plurality of light transmissive regions. Optionally, an orthographic projection of the intermediate layer IML on the base substrate BBS is at least partially non-overlapping with an orthographic projection of the color conversion layer CCL on the base substrate BBS, and is at least partially non-overlapping with an orthographic projection of the light transmissive layer LTL on the base substrate BBS.

The inventors of the present disclosure discover that, by having the intermediate layer IML at least partially absent in the plurality of light transmissive regions, the color conversion layer CCL and the light transmissive layer LTL can be made with an enhanced thickness, increasing light emission efficiency of the color conversion layer CCL.

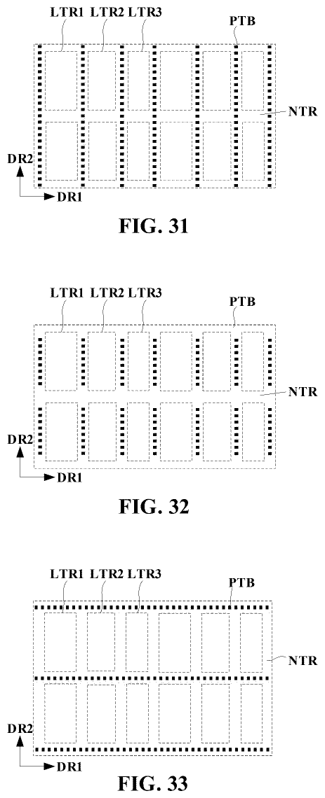

FIG. 30 is a cross-sectional view of a color conversion substrate in some embodiments according to the present disclosure. FIG. 31 is a plan view of a color conversion substrate in some embodiments according to the present disclosure. Referring to FIG. 30, FIG. 31, and FIG. 14, the plurality of pattern blocks PTB in some embodiments are at least partially in the plurality of column portions CP. In some embodiments, the plurality of pattern blocks PTB are at least partially absent in the plurality of row portions RP. Optionally, the plurality of pattern blocks PTB are absent in the plurality of row portions RP except for the plurality of intersection portions isp. In some embodiments, the plurality of pattern blocks PTB are at least partially in the plurality of first portions p1 of the light non-transmissive region NTR. Optionally, the plurality of pattern blocks PTB are at least partially in the plurality of first portions p1 of the light non-transmissive region NTR, and at least partially in the plurality of intersection portions isp of the light non-transmissive region NTR. Optionally, the plurality of pattern blocks PTB are at least partially absent in the plurality of second portions p2. Optionally, the plurality of pattern blocks PTB are completely absent in the plurality of second portions p2. In some embodiments, the plurality of pattern blocks PTB include a plurality of first arrays, a respective first array of the plurality of first arrays being in a respective column portion of the plurality of column portions CP. In some embodiments, pattern blocks in the respective first array is arranged in rows and columns. Optionally, a column of pattern blocks is arranged along a second direction DR2, and a row of pattern blocks is arranged along the first direction DR1. Optionally, the respective first array includes one column of pattern blocks as shown in FIG. 31.

FIG. 32 is a plan view of a color conversion substrate in some embodiments according to the present disclosure. Referring to FIG. 30, FIG. 32, and FIG. 14, the plurality of pattern blocks PTB in some embodiments are at least partially in the plurality of first portions p1. Optionally, the plurality of pattern blocks PTB are at least partially absent in the plurality of second portions p2. Optionally, the plurality of pattern blocks PTB are at least partially absent in the plurality of intersection portions isp. As shown in FIG. 13B, the plurality of pattern blocks PTB are absent in the plurality of second portions p2 and absent in the plurality of intersection portions isp.

FIG. 33 is a plan view of a color conversion substrate in some embodiments according to the present disclosure. Referring to FIG. 30, FIG. 33, and FIG. 14, the plurality of pattern blocks PTB in some embodiments are at least partially in the plurality of row portions RP. In some embodiments, the plurality of pattern blocks PTB are at least partially absent in the plurality of column portions CP. Optionally, the plurality of pattern blocks PTB are absent in the plurality of column portions CP except for the plurality of intersection portions isp. In some embodiments, the plurality of pattern blocks PTB are at least partially in the plurality of second portions p2 of the light non-transmissive region NTR. Optionally, the plurality of pattern blocks PTB are at least partially in the plurality of second portions p2 of the light non-transmissive region NTR, and at least partially in the plurality of intersection portions isp of the light non-transmissive region NTR. Optionally, the plurality of pattern blocks PTB are at least partially absent in the plurality of first portions p1. Optionally, the plurality of pattern blocks PTB are completely absent in the plurality of first portions p1. In some embodiments, the plurality of pattern blocks PTB include a plurality of second arrays, a respective second array of the plurality of second arrays being in a respective row portion of the plurality of row portions RP. In some embodiments, pattern blocks in the respective second array is arranged in rows and columns. Optionally, a column of pattern blocks is arranged along a second direction DR2, and a row of pattern blocks is arranged along the first direction DR1. Optionally, the respective second array includes one row of pattern blocks.

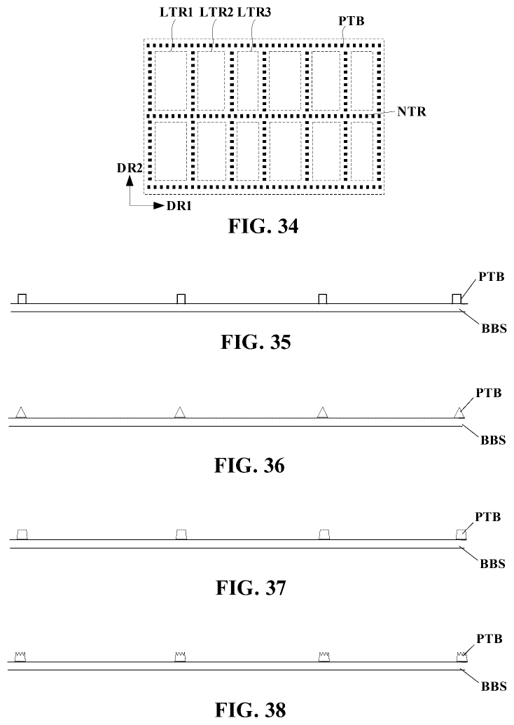

FIG. 34 is a plan view of a color conversion substrate in some embodiments according to the present disclosure. Referring to FIG. 30, FIG. 34, and FIG. 14, the plurality of pattern blocks PTB in some embodiments are at least partially in the plurality of column portions CP, and at least partially in the plurality of row portions RP. In some embodiments, the plurality of pattern blocks PTB are at least partially in the plurality of first portions p1 of the light non-transmissive region NTR, and are at least partially in the plurality of second portions p2. Optionally, the plurality of pattern blocks PTB are at least partially in the plurality of intersection portions isp of the light non-transmissive region NTR. In some embodiments, the plurality of pattern blocks PTB include a plurality of third arrays, a respective third array of the plurality of third arrays being in a respective first portion of the plurality of first portions p1. In some embodiments, pattern blocks in the respective third array is arranged in rows and columns. Optionally, a column of pattern blocks is arranged along a second direction DR2, and a row of pattern blocks is arranged along the first direction DR1. Optionally, the respective third array includes one column of pattern blocks. In some embodiments, the plurality of pattern blocks PTB include a plurality of fourth arrays, a respective fourth array of the plurality of fourth arrays being in a respective second portion of the plurality of second portions p2. In some embodiments, pattern blocks in the respective fourth array is arranged in rows and columns. Optionally, a column of pattern blocks is arranged along a second direction DR2, and a row of pattern blocks is arranged along the first direction DR1. Optionally, the respective fourth array includes one row of pattern blocks.

The respective pattern block may have various appropriate morphology. FIG. 35 is a cross-sectional view of a pattern layer in some embodiments according to the present disclosure. In some embodiments, referring to FIG. 35, in a cross-section along a plane perpendicular to the base substrate BBS and intersecting two adjacent pattern blocks of the plurality of pattern blocks PTB, the respective pattern block has a rectangular shape.

FIG. 36 is a cross-sectional view of a pattern layer in some embodiments according to the present disclosure. In some embodiments, referring to FIG. 36, in a cross-section along a plane perpendicular to the base substrate BBS and intersecting two adjacent pattern blocks of the plurality of pattern blocks PTB, the respective pattern block has a triangular shape.

FIG. 37 is a cross-sectional view of a pattern layer in some embodiments according to the present disclosure. In some embodiments, referring to FIG. 37, in a cross-section along a plane perpendicular to the base substrate BBS and intersecting two adjacent pattern blocks of the plurality of pattern blocks PTB, the respective pattern block has a trapezoidal shape.

FIG. 38 is a cross-sectional view of a pattern layer in some embodiments according to the present disclosure. In some embodiments, referring to FIG. 38, a side of the respective pattern block away from the base substrate BBS has a serrated surface. By having the serrated surface, the bank layer BL has an increased contact area with an underlying layer, and the bank layer BL can be better adhered.

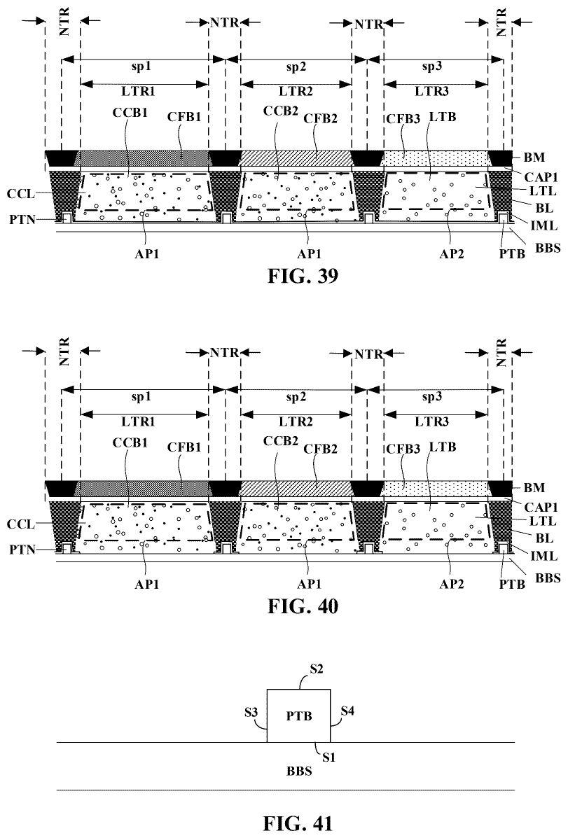

FIG. 39 is a cross-sectional view of a color conversion substrate in some embodiments according to the present disclosure. FIG. 40 is a cross-sectional view of a color conversion substrate in some embodiments according to the present disclosure. Referring to FIG. 39 and FIG. 40, the color conversion substrate in some embodiments includes a pattern layer PTN on a base substrate BBS; an intermediate layer IML on a side of the pattern layer PTN away from the base substrate BBS; a bank layer BL on a side of the intermediate layer IML away from the base substrate BBS; a plurality of first apertures AP1 and a plurality of second apertures AP2 extending through the bank layer BL; a color conversion layer CCL at least partially in the plurality of first apertures AP1; and a light transmissive layer LTL at least partially in the plurality of second apertures AP2.

Referring to FIG. 39, the intermediate layer IML in some embodiments extends over the plurality of light transmissive regions (e.g., the first light transmissive region LTR1, the second light transmissive region LTR2, or the third light transmissive region LTR3) and the light non-transmissive region NTR. In some embodiments, an orthographic projection of the intermediate layer IML on the base substrate BBS covers an orthographic projection of the color conversion layer CCL and the light transmissive layer LTL on the base substrate BBS.

Referring to FIG. 40, the intermediate layer IML in some embodiments is at least partially present in the light non-transmissive region NTR, and is at least partially absent in the plurality of light transmissive regions. Optionally, an orthographic projection of the intermediate layer IML on the base substrate BBS is at least partially non-overlapping with an orthographic projection of the color conversion layer CCL on the base substrate BBS, and is at least partially non-overlapping with an orthographic projection of the light transmissive layer LTL on the base substrate BBS.

FIG. 41 is a cross-sectional view of a respective pattern block in some embodiments according to the present disclosure. In some embodiments, referring to FIG. 41, in a cross-section along a plane perpendicular to the base substrate BBS and intersecting two adjacent pattern blocks of the plurality of pattern blocks PTB, the respective pattern block has a first side S1 in contact with the base substrate BBS, a second side S2 opposite to the first side S1, a third side S3 connecting the first side S1 and the second side S2, and a fourth side S4 connecting the first side S1 and the second side S2, the third side S3 and the fourth side S4 opposite to each other.

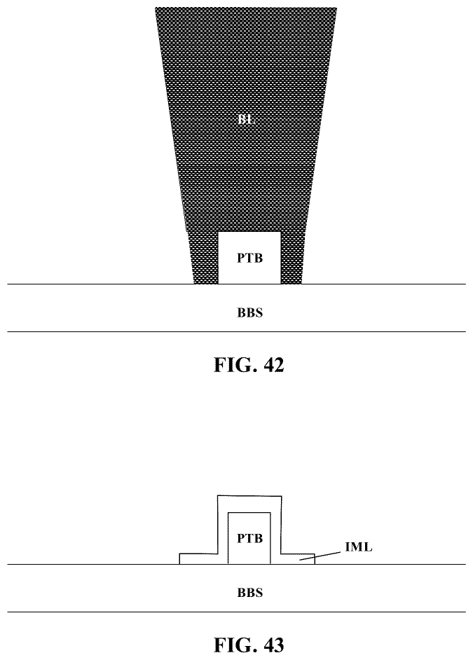

FIG. 42 is a cross-sectional view of a portion of a bank layer on a respective pattern block in some embodiments according to the present disclosure. Referring to FIG. 42, in some embodiments, the bank layer BL at least partially covers the second side S2, the third side S3, and the fourth side S4 of the respective pattern block.

Referring to FIG. 42, the respective pattern block in some embodiments protrudes into a recess in the bank layer BL. By having the respective pattern block protruding into the recess in the bank layer BL, a contact area between the bank layer BL and an underlying layer (e.g., the respective pattern block) can be increased, enhancing adhesion of the bank layer BL to the underlying layer.

FIG. 43 is a cross-sectional view of a portion of an intermediate layer on a respective pattern block in some embodiments according to the present disclosure. Referring to FIG. 41 and FIG. 43, in some embodiments, the intermediate layer IML at least partially covers the second side S2, the third side S3, and the fourth side S4 of the respective pattern block.

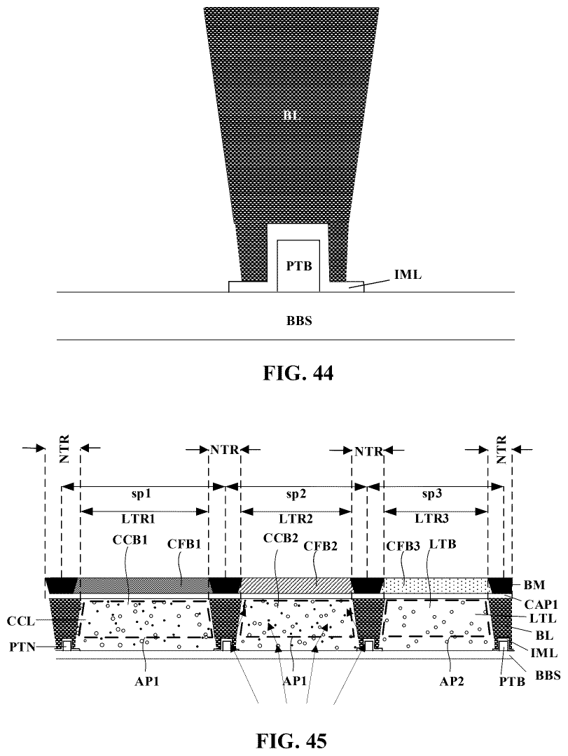

FIG. 44 is a cross-sectional view of a portion of a bank layer and a portion of an intermediate layer on a respective pattern block in some embodiments according to the present disclosure. Referring to FIG. 41, FIG. 43, and FIG. 44, in some embodiments, the bank layer BL at least partially covers a side of the portion of the intermediate layer IML that covers the second side S2 of the respective pattern block, at least partially covers a side of the portion of the intermediate layer IML that covers the third side S3 of the respective pattern block, and at least partially covers a side of the portion of the intermediate layer IML that covers the fourth side S4 of the respective pattern block.

Referring to FIG. 44, the respective pattern block and the portion of the intermediate layer IML in some embodiments protrudes into a recess in the bank layer BL. By having the respective pattern block and the portion of the intermediate layer IML protruding into the recess in the bank layer BL, a contact area between the bank layer BL and an underlying layer (e.g., the intermediate layer IML) can be increased, enhancing adhesion of the bank layer BL to the underlying layer.

In some embodiments, the intermediate layer IML has a first refractive index, and the pattern layer PTN has a second refractive index. Optionally, the first refractive index is greater than the second refractive index. In one example, the first refractive index is in a range of 1.6 to 1.8, and the second refractive index is in a range of 1.4 to 1.6. In one example, the intermediate layer IML has a thickness in a range of 0.5 μm to 2.0 μm.

In some embodiments, the base substrate BBS has a third refractive index, the intermediate layer IML has a first refractive index, and the pattern layer PTN has a second refractive index. Optionally, the third refractive index is greater than the first refractive index, and the first refractive index is greater than the second refractive index. In one example, the third refractive index is in a range of 1.80 to 1.90 (e.g., 1.85), the first refractive index is in a range of 1.70 to 1.75, and the second refractive index is in a range of 1.5 to 1.6.

FIG. 45 illustrates a light path in a color conversion substrate in some embodiments according to the present disclosure. Referring to FIG. 45, by having the first refractive index greater than the second refractive index, or having the third refractive index greater than the first refractive index, incident light irradiated on a respective pattern block can be refracted toward a center of a respective light transmissive region (e.g., the first light transmissive region LTR1, the second light transmissive region LTR2, or the third light transmissive region LTR3). For example, the incident light to the respective light transmissive region can be converged, leading to excitation of quantum dots materials with a better incident angle, thereby enhancing an enhanced quantum dots conversion rate.

In some embodiments, the plurality of pattern blocks PTB include a reflective material such as a metallic material. Incident light irradiated on a respective pattern block can be reflected by a surface of the respective pattern block toward a center of a respective light transmissive region (e.g., the first light transmissive region LTR1, the second light transmissive region LTR2, or the third light transmissive region LTR3), particularly for incident light with a relatively greater incident angle. Moreover, by having the third refractive index greater than the first refractive index, incident light with a relatively smaller incident angle can be refracted toward the center of a respective light transmissive region. The combination of the above mechanisms results in convergence of the incident light entered into the respective light transmissive region, leading to excitation of quantum dots materials with a better incident angle, thereby enhancing an enhanced quantum dots conversion rate.

In one example, the respective pattern block is made of a metallic material.

In an alternative example, the respective pattern block includes a reflective material and an insulating material. Optionally, the reflective material is on a side of the insulating material away from the base substrate BBS. Optionally, the respective pattern block includes a base portion and a coating portion on a side of the base portion away from the base substrate BBS. The coating portion is made of a reflective material such as a metallic material, and the base portion is made of an insulating material such as an organic insulating material. Optionally, the coating portion at least partially covers lateral surfaces of the base portion.

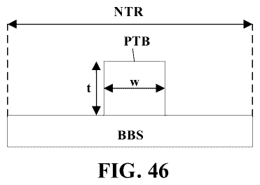

FIG. 46 is a cross-sectional view of a respective pattern block in some embodiments according to the present disclosure. Referring to FIG. 46, the respective pattern block has an average thickness t. In some embodiments, in a cross-section along a plane perpendicular to the base substrate BBS and intersecting two adjacent pattern blocks of the plurality of pattern blocks PTB, the respective pattern block has a width w.

In one example, 1 μm≤w≤10 μm.

In one example, 1 μm≤t≤5 μm.

In some embodiments, the bank layer has an average thickness t3. In some embodiments, 2≤t3/t≤10, e.g., 2≤t3/t≤3, 3≤t3/t≤4, 4≤t3/t1≤5, 5≤t3/t≤6, 6≤t3/t≤7, 7≤t3/t≤8, 8≤t3/t≤9, or 9≤t3/t≤10.

Referring to FIG. 9 to FIG. 12, FIG. 25 to FIG. 30, FIG. 39, FIG. 40, FIG. 42, FIG. 44, and FIG. 45, in some embodiments, a surface (e.g., a bottom surface) of the bank layer BL on a side closer to the pattern layer PTN has a shape conforming to a surface (e.g., a top surface) of the pattern layer PTN on a side closer to the bank layer BL. As used herein, the term “conforming” refers to a first layer (e.g., the bank layer BL) follows a topology of a surface of a second layer (e.g., the pattern layer) underneath the first layer, e.g., a bottom surface of the first layer has a topology substantially matching a topology of a top surface of the second layer. The term “conforming” may imply a complementary matching of two surfaces, but is not limited to complementary matching. The term “conforming” is interpreted in the present disclosure to include scenarios in which two surfaces are not completely complementary. For example, a third layer (e.g., the intermediate layer IML) is deposited on the second layer, and the first layer is deposited on the third layer. In this case, a bottom surface of the third layer has a topology substantially matching a topology of a top surface of the second layer, and a bottom surface of the first layer has a topology substantially matching a topology of a top surface of the third layer. The first layer is considered to be conforming to the second layer as long as the first layer substantially follows a topology of the top surface of the second layer. In one example, the topology of the top surface of the second layer includes a gap between two protruding structures, and the topology of the top surface of the third layer includes a groove in a corresponding position, and the first layer is considered to be conforming to the second layer when the first layer fills in the groove and in contact with the top surface of the third layer. Similarly, the interpretation applies to scenarios in which additional layer(s) are included between the first layer and the second layer.

Referring to FIG. 9, FIG. 10, FIG. 30, and FIG. 42, in some embodiments, the bank layer BL is in direct contact with the pattern layer PTN. At least a portion of the bottom surface of the bank layer BL has a shape complementary to a shape of at least a portion of the top surface of the pattern layer PTN. A surface (e.g., a bottom surface) of the bank layer BL on a side closer to the pattern layer PTN has a shape conforming to a surface (e.g., a top surface) of the pattern layer PTN on a side closer to the bank layer BL.

Referring to FIG. 11, FIG. 12, FIG. 25 to FIG. 29, FIG. 39, FIG. 40, FIG. 44, and FIG. 45, the bottom surface of the bank layer BL has a shape that is not completely complementary to a shape of the top surface of the pattern layer PTN, however, substantially follows a topology of the top surface of the pattern layer PTN. The bottom surface of the bank layer BL is considered to have a shape conforming to the top surface of the pattern layer PTN.

Referring to FIG. 9 to FIG. 12, FIG. 25 to FIG. 30, FIG. 39, FIG. 40, FIG. 42, FIG. 44, and FIG. 45, in some embodiments, an orthographic projection of a surface (e.g., a bottom surface) of the bank layer BL on a side closer to the pattern layer PTN on the base substrate BS at least partially overlaps with an orthographic projection of the plurality of pattern blocks PTB on the base substrate BS. Optionally, the orthographic projection of the surface of the bank layer BL on a side closer to the pattern layer PTN on the base substrate BS covers the orthographic projection of the plurality of pattern blocks PTB on the base substrate BS.

Optionally, an area of the orthographic projection of the surface of the bank layer BL on a side closer to the pattern layer PTN on the base substrate BS is greater than an area of the orthographic projection of the plurality of pattern blocks PTB on the base substrate BS. Optionally, the area of the orthographic projection of the surface of the bank layer BL on a side closer to the pattern layer PTN on the base substrate BS is at least 1.2 times (e.g., at least 1.3 times, at least 1.4 times, at least 1.5 times, at least 1.6 times, at least 1.7 times, at least 1.8 times, at least 1.9 times, at least 2.0 times, at least 2.1 times, at least 2.2 times, at least 2.3 times, at least 2.4 times, at least 2.5 times, at least 2.6 times, at least 2.7 times, at least 2.8 times, at least 2.9 times, at least 3.0 times, at least 3.1 times, at least 3.2 times, at least 3.3 times, at least 3.4 times, at least 3.5 times, at least 3.6 times, at least 3.7 times, at least 3.8 times, at least 3.9 times, at least 4.0 times, at least 4.1 times, at least 4.2 times, at least 4.3 times, at least 4.4 times, at least 4.5 times, at least 4.6 times, at least 4.7 times, at least 4.8 times, at least 4.9 times, or at least 5.0 times,) of the area of the orthographic projection of the plurality of pattern blocks PTB on the base substrate BS.

In another aspect, the present disclosure provides a display apparatus, including the color conversion substrate described herein or fabricated by a method described herein, and a plurality of light emitting elements between a first base substrate and the pattern layer. Examples of appropriate display apparatuses include, but are not limited to, an electronic paper, a mobile phone, a tablet computer, a television, a monitor, a notebook computer, a digital album, a GPS, etc.

In some embodiments, the display apparatus further includes an encapsulating layer encapsulating the plurality of light emitting elements. In some embodiments, the encapsulating layer includes a first inorganic encapsulating sublayer, an organic encapsulating sublayer on a side of the first inorganic encapsulating sublayer away from the plurality of light emitting elements, and a second inorganic encapsulating sublayer on a side of the organic encapsulating sublayer away from the plurality of light emitting elements. Optionally, the pattern layer is in direct contact with the second encapsulating sublayer.

In some embodiments, the display apparatus further includes a pixel definition layer defining a plurality of subpixel apertures. Optionally, an orthographic projection of the pixel definition layer on the base substrate covers an orthographic projection of the pattern layer on the base substrate.

In another aspect, the present disclosure provides a method of fabricating a color conversion substrate. In some embodiments, the method includes forming a pattern layer on a base substrate; forming a bank layer on a side of the pattern layer away from the base substrate; forming a color conversion layer at least partially in a plurality of first apertures extending through the bank layer, respectively; and forming a light transmissive layer at least partially in a plurality of second apertures extending through the bank layer, respectively. Optionally, forming the pattern layer comprises forming a plurality of pattern blocks. Optionally, a respective pattern block of the plurality of pattern blocks protrudes away from the base substrate toward the bank layer.

The foregoing description of the embodiments of the invention has been presented for purposes of illustration and description. It is not intended to be exhaustive or to limit the invention to the precise form or to exemplary embodiments disclosed. Accordingly, the foregoing description should be regarded as illustrative rather than restrictive. Obviously, many modifications and variations will be apparent to practitioners skilled in this art. The embodiments are chosen and described in order to explain the principles of the invention and its best mode practical application, thereby to enable persons skilled in the art to understand the invention for various embodiments and with various modifications as are suited to the particular use or implementation contemplated. It is intended that the scope of the invention be defined by the claims appended hereto and their equivalents in which all terms are meant in their broadest reasonable sense unless otherwise indicated. Therefore, the term “the invention”, “the present invention” or the like does not necessarily limit the claim scope to a specific embodiment, and the reference to exemplary embodiments of the invention does not imply a limitation on the invention, and no such limitation is to be inferred. The invention is limited only by the spirit and scope of the appended claims. Moreover, these claims may refer to use “first”, “second”, etc. following with noun or element. Such terms should be understood as a nomenclature and should not be construed as giving the limitation on the number of the elements modified by such nomenclature unless specific number has been given. Any advantages and benefits described may not apply to all embodiments of the invention. It should be appreciated that variations may be made in the embodiments described by persons skilled in the art without departing from the scope of the present invention as defined by the following claims. Moreover, no element and component in the present disclosure is intended to be dedicated to the public regardless of whether the element or component is explicitly recited in the following claims.

1. A color conversion substrate, comprising:
a base substrate;
a pattern layer on the base substrate;
a bank layer on a side of the pattern layer away from the base substrate;
a color conversion layer at least partially in a plurality of first apertures extending through the bank layer, respectively; and
a light transmissive layer at least partially in a plurality of second apertures extending through the bank layer, respectively;
wherein the pattern layer comprises a plurality of pattern blocks; and
a respective pattern block of the plurality of pattern blocks protrudes away from the base substrate toward the bank layer.

2. The color conversion substrate of claim 1, wherein a surface of the bank layer on a side closer to the pattern layer has a shape conforming to a surface of the pattern layer on a side closer to the bank layer.

3. The color conversion substrate of claim 1, wherein the pattern layer and the bank layer are at least partially in a light non-transmissive region;
the pattern layer and the bank layer are at least partially absent in a plurality of light transmissive regions; and
an orthographic projection of the bank layer on the base substrate at least partially overlaps with an orthographic projection of the respective pattern block on the base substrate.

4. The color conversion substrate of claim 1, wherein an orthographic projection of a surface of the bank layer on a side closer to the pattern layer on the base substrate covers an orthographic projection of the plurality of pattern blocks on the base substrate; and
an area of the orthographic projection of the surface of the bank layer on a side closer to the pattern layer on the base substrate is at least 1.2 times of an area of the orthographic projection of the plurality of pattern blocks on the base substrate.

5. The color conversion substrate of claim 1, wherein the respective pattern block is in direct contact with the bank layer.

6. The color conversion substrate of claim 1, further comprising an intermediate layer on a side of the pattern layer away from the base substrate, and on a side of the bank layer closer to the base substrate;
wherein the respective pattern block is in direct contact with the intermediate layer; and
the intermediate layer is in direct contact with the bank layer.

7. The color conversion substrate of claim 6, wherein the intermediate layer is at least partially present in a light non-transmissive region, and is at least partially absent in a plurality of light transmissive regions; and
an orthographic projection of the intermediate layer on the base substrate is at least partially non-overlapping with an orthographic projection of the color conversion layer on the base substrate, and is at least partially non-overlapping with an orthographic projection of the light transmissive layer on the base substrate.

8. The color conversion substrate of claim 1, wherein the plurality of pattern blocks comprise a first adjacent pattern block and a second adjacent pattern block in a portion of a light non-transmissive region between a first adjacent light transmissive region and a second adjacent light transmissive region of a plurality of light transmissive regions.

9. The color conversion substrate of claim 8, wherein a portion of the bank layer at least partially extends into a gap between the first adjacent pattern block and the second adjacent pattern block, and is in direct contact with the first adjacent pattern block and the second adjacent pattern block.

10. The color conversion substrate of claim 8, further comprising:
an intermediate layer on a side of the first adjacent pattern block and the second adjacent pattern block away from the base substrate, the intermediate layer at least partially extending into a gap between the first adjacent pattern block and the second adjacent pattern block, and being in direct contact with the first adjacent pattern block and the second adjacent pattern block; and
a groove extending into a portion of the intermediate layer at least partially extending into the gap;
wherein a portion of the bank layer at least partially extends into the groove, and is in direct contact with the intermediate layer.

11. The color conversion substrate of claim 1, wherein the respective pattern block has a first side in contact with the base substrate, a second side opposite to the first side, a third side connecting the first side and the second side, and a fourth side connecting the first side and the second side, the third side and the fourth side opposite to each other.

12. The color conversion substrate of claim 11, wherein the bank layer at least partially covers the second side, the third side, and the fourth side of the respective pattern block.

13. The color conversion substrate of claim 11, further comprising an intermediate layer on a side of the respective pattern block away from the base substrate;
wherein the intermediate layer at least partially covers the second side, the third side, and the fourth side of the respective pattern block; and
the bank layer at least partially covers a side of a portion of the intermediate layer that covers the second side of the respective pattern block, at least partially covers a side of a portion of the intermediate layer that covers the third side of the respective pattern block, and at least partially covers a side of a portion of the intermediate layer that covers the fourth side of the respective pattern block.

14. The color conversion substrate of claim 6, wherein the intermediate layer has a first refractive index;
the pattern layer has a second refractive index;
the base substrate has a third refractive index;
the third refractive index is greater than the first refractive index; and
the first refractive index is greater than the second refractive index.

15. The color conversion substrate of claim 14, wherein the first refractive index is in a range of 1.6 to 1.8;
the second refractive index is in a range of 1.4 to 1.6; and
the third refractive index is in a range of 1.80 to 1.90.

16. The color conversion substrate of claim 1, wherein the respective pattern block comprises a reflective material.

17. The color conversion substrate of claim 16, wherein the respective pattern block comprises a metallic material.

18. The color conversion substrate of claim 1, wherein the respective pattern block has an average thickness;
the bank layer has a third average thickness; and
a ratio of the third average thickness to the average thickness is in a range of 2 to 10.

19. The color conversion substrate of claim 8, wherein the first adjacent pattern block has a first average thickness;
the second adjacent pattern block has a second average thickness;
the bank layer has a third average thickness;
a ratio of the third average thickness to the first average thickness is in a range of to 10; and
a ratio of the third average thickness to the second average thickness is in a range of 2 to 10.

20. (canceled)

21. A display apparatus, comprising the color conversion substrate of claim 1, and a plurality of light emitting elements between a first base substrate and the pattern layer.

22. (canceled)

23. (canceled)
